(19) United States
(12) Patent Application Publication
(10) Pub. No.: US 2024/0092809 A1
(43) Pub. Date: Mar. 21, 2024

(54) HIGHLY THERMALLY CONDUCTIVE, ULTRA-LOW-K TWO-DIMENSIONAL COVALENT ORGANIC FRAMEWORK DIELECTRIC LAYERS

(71) Applicants: Northwestern University, Evanston, IL (US); University of Virginia Patent Foundation, Charlottesville, VA (US)

(72) Inventors: Austin Michael Evans, Evanston, IL (US); William Robert Dichtel, Evanston, IL (US); Mark C. Hersam, Evanston, IL (US); Vinod Kumar Sangwan, Evanston, IL (US); Ioannina Castano, Evanston, IL (US); Patrick E. Hopkins, Charlottesville, VA (US); Ashutosh Giri, Charlottesville, VA (US)

(21) Appl. No.: 18/262,537

(22) PCT Filed: Jan. 21, 2022
(86) PCT No.: PCT/US22/13260

§ 371 Date: Jul. 21, 2023

Related U.S. Application Data
(60) Provisional application No. 63/140,141, filed on Jan. 21, 2021.

(51) Int. Cl. C07F 5/04

(52) U.S. Cl. CPC C07F 5/04; H01L 28/40

(57) ABSTRACT

Disclosed herein are low dielectric constant (low-k) two-dimensional covalent organic framework materials that have a dielectric constant k less than 2.4, optionally less than 1.9, and are comprised of regularly porous, covalently linked, layer structures.

### CROSS-REFERENCE TO RELATED APPLICATIONS

This application claims benefit of priority to U.S. Patent Application Ser. No. 63/140,141, filed Jan. 21, 2021, the contents of which is incorporated by reference in its entirety.

### STATEMENT REGARDING FEDERALLY SPONSORED RESEARCH

This invention was made with government support under grant numbers W911NF-15-1-0447 awarded by Army Research Office (ARO) and N00014-20-1-2686 awarded by Office of Naval Research (ONR). The government has certain rights in the invention.

### FIELD OF THE INVENTION

The disclosed technology is generally directed to covalent organic framework materials. More particularly the technology is directed to highly thermally conductive, ultra-low k two-dimensional covalent organic framework dielectric layers.

### BACKGROUND OF THE INVENTION

To take advantage of sub-10 nanometer integrated circuit components, interlayer low-dielectric constant (low-k) materials with high thermal conductivities must be developed. As dielectric layers have thinned, electronic crosstalk and capacitive signal delay significantly diminish device performance. The Semiconductor Industry Association has identified the development of mechanically robust, thermally stable, few-nanometer, low-k (k<2.4) and ultra-low-k (k<1.9) materials as needed to address this challenge. Ultimately, the realization of such materials will reduce parasitic capacitance, enabling faster gate operations and minimizing dynamic power dissipation. To realize this goal, it is necessary that low-k dielectric materials and thin film (<200 nm) fabrication techniques be advanced. Towards this end, two major classes of low-k dielectric materials have been developed: 1) organic materials that are inherently low-k because of the limited polarizability of covalent bonds and 2) porous oxides that are low-k as a result of their large free volumes. However, all known low-k materials have large thermal resistances that arise from their disordered morphologies and high porosities, which limit high power density chip performance due to inadequate heat management.

### BRIEF SUMMARY OF THE INVENTION

Disclosed herein are low dielectric constant (low-k) two-dimensional covalent organic framework materials that have a dielectric constant k less than 2.4 and, in some embodiments, less than 1.9. Suitably the 2-D COFs comprise regularly porous, covalently linked, layer structures that may be prepare from a variety of starting materials.

An advantage of the presently disclosed COFs is that they possess a high thermal conductivity. Suitably, thermal conductivity κ may be greater than 0.8 W m⁻¹ K⁻¹ in a cross-plane direction. In some embodiments, the thermal conductivity anisotropy ratio is greater than 3 between an in-plane thermal conductivity and a cross-plane thermal conductivity.

The COFs having the properties described herein are high-quality COF thin films. In some embodiments, the COFs have a cross-plan thickness of less than 75 nm. An advantage of the presently disclosed technology is that the thickness of the film may be controlled by sequentially applying fresh starting material. The COFs described herein are substantially uniform and free of contamination. In some embodiments, the COFs have a root-mean-square roughness less than 5 nm.

The Examples demonstrate the preparation of these COFs via boronate ester linking chemistries, but other chemistries may also be used to prepare these materials. The COFs may be prepared from poly-ol or catechols and a difunctional aryl boronic acid, such as PBBA, PyBA, BBBA, DPB-BA, or IBBA, but other building units and linking groups may also be used to prepare low-k materials.

Another aspect of the invention provides for heterostructures comprising any of the two-dimensional COFs described herein and further comprising a templating substrate. The templating substrate may provide significant van der Waals or other suitable interaction that allows for nucleation of the COF on the substrate. To encourage nucleation of thin layer films, the templating structure may comprise a thin film such as monolayer graphene or monolayer MoS₂. Such thin films may be prepared by a number of different methods such as growth, chemical vapor deposition, or graphitization on a support. Suitably the templating substrate may also comprise a support. Many different supports may be employed that are amenable to the described polymerization strategy and that could survive conditions sufficient for preparing the COFs described herein, such as temperature, time, and solvent requirements. An exemplary support may comprise Si, such as SiC.

Another aspect of the invention provides for dielectric bilayers comprising any of the two-dimensional COFs described herein and further comprising a blocking layer configured to minimize leakage current. The blocking layer may be comprised of an inorganic dielectric layer, such as a metal oxide. Exemplary inorganic dielectric layers may be comprised of Al₂O₃, HfO₂, ZrO₂, ZnO, TiO₂, SiO₂, or Ta₂O₅, and the like. The blocking layer may be a thin film. Suitably, the blocking layer is less than 10 nm, and as little as about 0.3 nm, when prepared via atomic layer deposition.

Another aspect of the invention provides for capacitors that may be prepared from any of the two-dimensional COFs described herein positioned between two conductive plates.

Another aspect of the invention provides for preparing any of the two-dimensional COFs described herein. The method may comprise contacting a solution with a templating substrate in a reaction vessel under conditions sufficient for preparing a covalent organic framework, whereby a heterotructure comprising a first layer of two-dimensional covalent organic framework deposited on the templating substrate and a liquid phase is formed within the reaction vessel, and removing an insoluble covalent organic framework dispersed within the liquid phase, wherein the solution comprises a plurality of building units, a plurality of linking units, and a solvent. The solvent should be selected to ensure that the monomers are solubilized by the mixture and the solvent mixture stabilizes the COF as a colloidal suspension. In some embodiments, the solvent comprises a Lewis basic solvent, such as a nitrile. In some embodiments, the Lewis basic solvent comprises at least 25% vol.

In some embodiments, the method may further comprise contacting the heterostructure with the solution in the reaction vessel having the insoluble covalent organic framework removed therefrom under conditions sufficient for preparing the covalent organic framework, whereby an additional layer of two-dimensional covalent organic framework is deposited on the heterostructure. Such a step may be repeated one or more times to provide for the desired thickness. In some embodiments, the removing step comprises decanting a portion of the liquid phase from the reaction vessel and diluting, with additional solvent, the liquid phase remaining within the reaction vessel. In some embodiments, at least 80% of the liquid phase is decanted but more or less of the liquid phase may be decanted.

### BRIEF DESCRIPTION OF THE DRAWINGS

Non-limiting embodiments of the present invention will be described by way of example with reference to the accompanying figures, which are schematic and are not intended to be drawn to scale. In the figures, each identical or nearly identical component illustrated is typically represented by a single numeral. For purposes of clarity, not every component is labeled in every figure, nor is every component of each embodiment of the invention shown where illustration is not necessary to allow those of ordinary skill in the art to understand the invention.

FIG. 1. Templated colloidal polymerization of boronate-ester linked COF films. A) Synthesis and structure of an exemplary boronate-ester linked COF films. B) Grazing-incidence wide-angle X-ray scattering patterns of COF films. C) Sequential polymerization of an exemplary COF film by introduction of monomer. D) Atomic force micrographs of sequentially polymerized TP-COF films. E) Line-cuts of sequentially polymerized TP-COF films in D.

FIG. 2. Optoelectronic properties of COF films. A) Electronic band structures calculated at the DFT/PBE0 level for COF-5 and the corresponding Brillouin zone. B) Electronic dielectric tensors calculated at the DFT/PBE level for all COFs studied C) Optical absorption and emission (λ_{Excitation}=325 nm) profiles for COF-5. D) Polarization dependent emission of COF-5 films, that resolves the in-plane (0°) component from the cross-plane (90°) component.

FIG. 3. COF-5 dielectric layer impedance measurements. A) Schematic of Au contacted Al₂O₃/COF-5 dielectric bilayer capacitors grown on epitaxial graphene (EG)/SiC wafers. B) Optical microscopy image of a patterned array of Au pads on full coverage A1203/COF-5/EG/SiC. The area of each Au pad is roughly 100,000 μm² (10⁻⁸ m²). C) AFM micrograph of the Al₂O₃/COF bilayer revealing a step edge at a scratch. D) Height profile extracted from the AFM green linecut in FIG. 3C. E) X-ray reflectivity (XRR) data and the model fit of the Al₂O₃/COF-5/EG/SiC layered structure. Inset: Extracted electron density profile from XRR fit. F) Leakage current versus the applied bias voltage across ten different COF devices. G) Capacitance of the Al₂O₃/COF-5 bilayer as a function of applied voltage measured at 1 kHz with a 100 mV signal. Inset: Modeled equivalent circuit of impedance behavior fit in FIG. 3H. H) Bode plots of the real (resistance, Z′) and imaginary (reactance, Z″) impedance components and respective model fits.

FIG. 4. Thermal Properties of 2D COF Thin Films. A) Characteristic TDTR data as a function of pump-probe delay time and analytical model fits. Inset: picosecond acoustics. B) Contour plots of thermal conductivity and heat capacity at a 95% confidence interval. C) Molecular dynamics simulations of temperature-dependent thermal conductivities. Dashed lines represent analytical fits generated from the temperature dependence shown. D) Density and thermal conductivity of common materials.

FIG. 5. Meta-analysis of thermal conductivities in low-k dielectrics. Filled diamonds are experimentally measured thermal conductivities and open diamonds are evaluated using computational techniques. For initial reports of the values included in the plot we direct the reader to the supplementary information.

FIG. 6. ¹H nuclear magnetic resonance spectra of 2,3,6,7,10,11 Hexahydroxytriphenylene Hydrate (HHTP), purchased from TCI America.

FIG. 7. ¹H nuclear magnetic resonance spectra of 1,4-phenylenebisboronic acid (PBBA), purchased from Sigma Aldrich.

FIG. 8. ¹H nuclear magnetic resonance spectra of 4,4′ -biphenylbisboronic acid (BBBA), purchased from Sigma Aldrich

FIG. 9. A) Atomic force micrograph of COF-5 film used for thermal property measurement B) Atomic force micrograph of TP-COF film used for thermal property measurement C) COF-5 film prepared using colloidal conditions D) Atomic force micrograph of COF-5 film prepared using previously reported solvothermal conditions.⁷ E) Atomic force micrograph of COF-10 produced using colloidal conditions F) Atomic force micrograph of TP-COF produced using colloidal conditions G) Atomic force micrograph of COF-117 produced using colloidal conditions H) Atomic force micrograph of DPB-COF produced using colloidal conditions.

FIG. 10. A) 2D Grazing-incidence X-ray diffraction Pattern of COF-5/SiO₂/Si grown by colloidal conditions B) 2D Grazing-incidence X-ray diffraction Pattern of COF-10/SiO₂/Si grown by colloidal conditions C) 2D Grazing-incidence X-ray diffraction Pattern of TP-COF/SiO₂/Si grown by colloidal conditions D) 2D Grazing-incidence X-ray diffraction Pattern of DPB-COF/SiO₂/Si grown by colloidal conditions E) 2D Grazing-incidence X-ray diffraction Pattern of COF-117/SiO₂/Si grown by colloidal conditions F) 2D Grazing-incidence X-ray diffraction Pattern of TP-COF/SiO₂/Si grown by colloidal conditions after one monomer polymerization cycle G) 2D Grazing-incidence X-ray diffraction Pattern of TP-COF/SiO₂/Si grown by colloidal conditions after two monomer polymerization cycles H) 2D Grazing-incidence X-ray diffraction Pattern of TP-COF/SiO₂/Si grown by colloidal conditions after three monomer polymerization cycles

FIG. 11. 2D Grazing-incidence X-ray diffraction Patterns of COF-5/SiO₂/Si polymerized from different initial monomer concentrations under colloidal conditions.

FIG. 12. 2D Grazing-incidence X-ray diffraction Patterns of COF-5/SiO₂/Si polymerized from solvothermal noncolloidal conditions.⁷

FIG. 13. 2D Grazing-incidence X-ray diffraction Patterns of TP-COF/MoS₂/Al₂O₃ polymerized from solvothermal noncolloidal conditions

FIG. 14. Polarization dependent emission of TP-COF films

FIG. 15. Polarization dependent emission of COF-5 films produced via solvothermal synthesis

FIG. 16. Cross-sectional scanning electron micrograph of COF-5/Al₂O₃/EG/SiC.

FIG. 17. X-ray reflectivity profiles of COF-5/EG/SiC. Inset: Extracted Electron Density Profile.

FIG. 18. X-ray reflectivity data a fit of COF-5/EG/SiO₂/Si. Inset: Electron density profile extracted from the XRR fit

FIG. 19. A), B) Bode plots showing tight distribution of real and imaginary parts of the impedance for 10 different COF-5 devices across the EG/SiC chip. The extracted capacitance is found vary by less than 10% over an area of 25 mm² C) Plot of negative reactance (−Z″) versus frequency of a Al₂O₃/COF-5 dielectric bilayer capacitor in ambient (relative humidity ˜62%) and in vacuum (pressure=2×10-5 torr). D)-E) Plot of negative reactance (−Z″) of two different Al₂O₃ dielectric bilayer capacitor devices as a function of temperature (−40° C.-110° C.). F) Plot of the normalized dielectric constant across this temperature range for two devices, demonstrating that the dielectric constant is invariant across this temperature range.

FIG. 20. Sensitivity of the ratio of the in-phase (Vᵢₙ) and out-of-phase (Vₒᵤₜ) signals for COF-5 at 8.8 MHz modulation frequency.

FIG. 21. A) Characteristic TDTR data along with the best-fit curve for TP-COF. B) Sensitivity contour plot showing the interrelationship between the measured heat capacity and thermal conductivity of our 2D TP-COF.

FIG. 22. Phase delay data and fit as a function of modulation frequency for a representative FDTR experiment.

FIG. 23. Analytical fits to the TDTR experimental data with different values of thermal boundary conductances across Al/COF interface h_{K,1}, while other parameters in the thermal model 5 are unchanged.

FIG. 24. Sensitivity contour plot showing the interrelationship between thermal boundary conductance and thermal conductivity of our 2D COFs.

FIG. 25. TDTR data for COF-5 films of 40 nm and 80 nm thickness along with the best-fit curves. The solid lines represent two-layer thermal model (for an Al/SiO₂ system) with thermal boundary conductance (h_{K}) as fitting parameter. The dashed and dotted-dashed lines represent three-layer thermal model with high interfacial resistances (R_{K}) across the COF-5/graphene/SiO₂ interface (R_{K,2}˜10⁻⁷ m² K W⁻¹; h_{K,2}˜10 MW m⁻² K⁻¹) for 40 nm and 80 nm COF-5 thicknesses. A high interfacial resistance would result in poor fits to the experimental data, which suggests that interfacial resistances are much lower than the bulk resistance posed by the 2D COF thin film. As such, the film is predominantly sensitive to the intrinsic thermal resistance of the 2D COF in this measurement.

FIG. 26. Contours at 1.2 ×Minimum MSE for FDTR data averaged over four experiments for COF-5, as a function of assumed heat capacity and thermal conductivity for 3.2 μm (red dashed line) and 3.3 μm (blue dashed line) pump-probe spot radii A) without a resistance at the interface and B) with a finite thermal boundary conductance at the COF-5/SLG/SiO₂ (h_{K,2}˜30 MW m⁻² K⁻¹). For comparison, the contour from our TDTR measurement on the same sample is also included.

### DETAILED DESCRIPTION OF THE INVENTION

Here we report the fabrication of high-quality COF thin films, which enable time- and frequency-domain thermoreflectance and impedance spectroscopy measurements. These measurements reveal that 2D COFs have high thermal conductivities for porous solids with ultra-low dielectric permittivities. These results show that oriented, layered 2D polymers are promising next-generation dielectric layers and that these molecularly precise materials offer unique and tunable property combinations.

As the features of microprocessors continue to be miniaturized, low dielectric constant (low-k) materials are necessary to limit electronic crosstalk, charge buildup, and signal propagation delay. However, all known low-k dielectrics exhibit low thermal conductivities, which complicate heat dissipation in high power-density chips. 2D covalent organic frameworks (2D COFs) combine immense permanent porosities, which may lead to low dielectric permittivities, and periodic layered structures, which may grant relatively high thermal conductivities. However, conventional synthetic routes produce 2D COFs that are unsuitable for the evaluation of these properties and integration into devices.

Two-dimensional covalent organic frameworks (2D COFs) are a class of modular, molecularly precise, highly porous, layered polymer sheets. These attributes impart a unique combination of physical properties compared to conventional polymers, such as high thermomechanical stabilities and low densities. Challenges associated with characterizing conventionally isolated polycrystalline COF powders have restricted the exploration of many 2D COF properties. To address this challenge, COFs have been fabricated as thin films via direct growth, exfoliation, or interfacial polymerization. However, none of these methods have proven general for wafer-scale synthesis of oriented and crystalline COF films without powder contamination. Synthetic limitations have hindered the evaluation of COFs' fundamental properties related to their use as low-k dielectric layers.

As used herein, a “covalent organic framework” or “COF” is a two- or three-dimensional organic solid with extended, periodic, and porous structures in which a plurality of linking groups (LGs) and functional building units (FBUs) are linked by covalent bonds. Suitably, COFs may be made entirely from light elements (e.g., H, B, C, N, and O). Two-dimensional COFs can self-assemble into larger structures. In some embodiments, layered 2D COF sheets adopt nearly eclipsed stacked structures, providing continuous nanometer-scale channels normal to the stacking direction, as well as significant π-orbital overlap between monomers in adjacent layers. These features can provide an accessible high surface area interface.

Dielectric constant, or relative permittivity, means the factor by which the electric field between charges is decreased in a material relative to vacuum. In some embodiments, the materials described herein may be a low-k dielectric material. A low-k dielectric material has a smaller dielectric constant relative to silicon dioxide. In some embodiments, the COFs described herein are low-k materials that have a dielectric constant less than 2.4 2.3, 2.2, 2.1, or 2.0. In particular embodiments, the COFs described herein as low-k materials may be ultra-low-k materials that have a dielectric constant less than 1.9.

COFs are crystalline. For example, the COFs can form crystallites (i.e., discrete structures) where the longest dimension of the crystallites can be from 50 nm to 10 microns, including all values to the nanometer and ranges of nanometers therebetween. In various embodiments, COFs can comprise at least 2 unit cells.

COFs, as well as other materials described herein, may be present as a thin film. A film may have a thickness of 0.3 nm to 10 microns, including all values and ranges therebetween. In some embodiments, the COF thin film has a thickness of 10 nm to 1 micron, 10 nm 800 nm, 10 nm to 600 nm, 10 nm to 400 nm, 10 nm to 200 nm, 10 nm to 100 nm, 10 nm to 75 nm, 10 nm to 50 nm, 10 nm to 25 nm, including all values and ranges therebetween.

COF are porous materials. In some embodiments, COFs are microporous, i.e., have pores with a longest dimension of less than 2 nm, or mesoporous, i.e., have pores with a longest dimension of 2 nm to 50 nm. The porous structure may form a repeating pattern rather than a random distribution of pores. In an embodiment, the framework has pores, where the pores run parallel to the stacked aromatic moieties.

COFs can have high surface areas. COFs can have surface areas ranging from 500 m²/g to 3000 m²/g, including all values to the m²/g and ranges of surface area therebetween. The surface area of the COFs can be determined by methods known in the art, for example, by BET analysis of gas (e.g., nitrogen) adsorption isotherms.

A “building unit” or “BU” comprises a molecular subunit having two or more functional termini that can be covalently bonded to an equal number of different linker groups (LGs). The covalent linkages between the BUs and LGs provide robust materials with precise and predictable control over composition, topology, and porosity. The relative geometries of the functional termini in the starting materials determine the COF topology.

A “linking group” or “LG” comprises a molecular subunit having two or more functional termini that can be covalently bonded to an equal number of BUs. In some embodiments, at least three BUs are each connected to a LG by covalent bond(s) or at least three LGs are each connected to a BU by covalent bond(s). For example, a BU and a LG may be connected by at least one covalent bond. In other examples, the BUs and LGs are connected by one covalent bond, two covalent bonds, or three covalent bonds. The BUs and LGs can be connected by, for example, carbon-boron bonds, carbon-nitrogen bonds (e.g., an imine bond or a hydrazone bond), carbon-oxygen bonds, carbon-carbon bonds, or boron-oxygen bonds (e.g., boronate ester bonds). Suitable chemistries for preparing COF materials include boronate-ester, imine, ketoenamine, Knoevenagle, and other suitable chemistries.

BUs and LGs may be selected to prepare a COF having a desired geometry, crystalline structure, chemical functionality, and/or porosity. Exemplary BUs and LGs may be selected to allow for the formation of COFs having 2-D arrangements. BUs and LGs suitable for formation of 2D COFs include, without limitation, BUs and LGs having linear, trigonal planar, square planar, or hexagonal planar geometries. BUs and LGs suitable for formation of 3D COFs include, without limitation, BUs or LGs having tetrahedral or octahedral geometries. Suitably, the COFs may comprise BUs or LGs having trigonal planar geometries such as 1,3,5-trisphenyl benzene groups.

In some embodiments, the BU and/or LG is comprised of an aryl moiety but BUs or LGs without an aryl moiety may also be used. The term “aryl” is art-recognized and refers to a carbocyclic aromatic group. Representative aryl groups include phenyl, naphthyl, anthracenyl, and the like. The term “aryl” includes polycyclic ring systems having two or more carbocyclic rings in which two or more carbons are common to two adjoining rings (the rings are “fused rings”) wherein at least one of the rings is aromatic and, e.g., the other ring(s) may be a cycloalkyl, cycloalkenyl, cycloalkynyl, and/or aryls. The term “aryl” includes polycyclic ring systems having two or more carbocyclic rings in which one carbon is common to a directly-adjoining ring (e.g., a biphenyl) or an indirectly adjoining ring, where the indirectly a joining rings are linked by a linker comprising one or more atoms (e.g., diphenylbutadiyne), wherein at least one of the rings is aromatic and, e.g., the other ring(s) may be a cycloalkyl, cycloalkenyl, cycloalkynyl, and/or aryls. Unless specified otherwise, the aromatic ring may be substituted at one or more ring positions with, for example, halogen, azide, alkyl, aralkyl, alkenyl, alkynyl, cycloalkyl, hydroxyl, alkoxyl, amino, nitro, sulfhydryl, imino, amido, carboxylic acid, —C(O)alkyl, —CO₂alkyl, carbonyl, carboxyl, alkylthio, sulfonyl, sulfonamido, sulfonamide, ketone, aldehyde, ester, heterocyclyl, aryl or heteroaryl moieties, or the like. In certain embodiments, the aromatic ring is substituted at one or more ring positions with an amine-terminated substituent or azide-terminated substituents, which may be useful in preparing the amine substituted COF. In certain other embodiments, the aromatic ring is not substituted, i.e., it is unsubstituted. In certain embodiments, the aryl group is a 6-10 membered ring structure. In some embodiments, the LG is comprised of a poly-ol or catechol. Exemplary poly-ols or catechols include HHTP, porphyrins, phthalocyanines, macrocyclic catechols, and the like.

In some embodiments, the BU comprises two or more boric acid moieties. When the BU comprises boric acid moieties and the LG comprises hydroxyl groups, boron-oxygen bonds may be formed. Exemplary BUs include, without limitation, PBBA, PyBA, BBBA, DPB-BA, or IBBA.

The Examples demonstrate the synthesis of high-quality wafer-scale 2D COF films through a templated colloidal approach. The templated colloidal approach described herein prevents powder contamination. Although it was known that supported graphene substrates template the formation of oriented 2D COF thin films, films obtained by this method are often unsuitable for device measurements because of contamination by insoluble COF powders that form during the synthesis. Here, colloidal approaches are used to grow COF thin films of few-nm roughness with controllable thicknesses on device-relevant substrates without contamination by insoluble precipitates. The robustness of this technique is demonstrated with five different 2D COFs, including a previously unreported structure, which are synthesized on different templating substrates. Furthermore, these 2D COF films are amenable to sequential polymerization cycles, enabling nanometer precise thickness control not possible in traditional precipitant-contaminated solvothermal syntheses.

The solution-stable colloidal suspension comprises a dispersion of COF crystals in a continuous phase. The use of solution-stable colloidal suspensions prevents the precipitation of insoluble COF products dispersed within the liquid phase. The insoluble COF crystals may have a diameter from about 10-2000 nm, including any value or range therebetween. For example, the COF crystals may have a diameter of 20-200 nm or 30-100 nm. Methods of preparing colloidal COFs are disclosed in Smith, B. J. et al. Colloidal covalent organic frameworks. ACS Cent. Sci. 3, 58-65 (2017); Evans, A. M.; et al., Seeded Growth of Single-Crystal Two-Dimensional Covalent Organic Frameworks. Science 2018, 361, 52-57; Rodríguez-San-Miguel, D. & Zamora, F. Processing of covalent organic frameworks: an ingredient for a material to succeed. Chem. Soc. Rev. 48, 4375-4386 (2019); and Li, H. et al. Nucleation-Elongation Dynamics of Two-Dimensional Covalent Organic Frameworks. J. Am. Chem. Soc. 142, 1367-1374 (2020). The use of Lewis basic solvents, such as nitrile cosolvents, prevents the precipitation of insoluble products and provides insoluble COFs crystals as a solution-stable colloidal suspension.

The unprecedented quality of these films enables the measurement of thermomechanical and optoelectronic properties of COF films. Optical absorption and emission spectroscopies showed that boronate ester-linked COF films are electronically insulating. These results are consistent with density functional theory (DFT) calculations that predict pristine COF-5 films have an indirect electronic bandgap of 3.6 eV and a direct bandgap of 3.9 eV. Impedance spectroscopy performed on COF-5 thin films reveals that they are electronically insulating, ultra-low-k (k<1.7) dielectric layers, which are consistent with DFT-calculated low electronic dielectric tensors (ε_{xx,yy,zz}<2) for all COFs investigated.

Due to their regularly porous, covalently linked, layered structure, 2D COFs circumvent the low thermal conductivities that afflict leading low-k dielectrics. Using time- and frequency-domain thermoreflectance (TDTR and FDTR, respectively) and molecular dynamics (MD) simulations, it is found that 2D COFs have a unique combination of low densities (ρ<1 g cm⁻³) and relatively high thermal conductivities (κ>0.8 W m⁻¹ K⁻¹ in the cross-plane direction with a predicted anisotropy ratio of >3 in the in-plane direction). These findings show that 2D COFs may be prepared as ultra-low-k dielectrics with desirable heat management characteristics. More broadly, accessing high-quality 2D COF thin films provides a means to rationally design solid-state organic materials to unlock technologically useful combinations of properties.

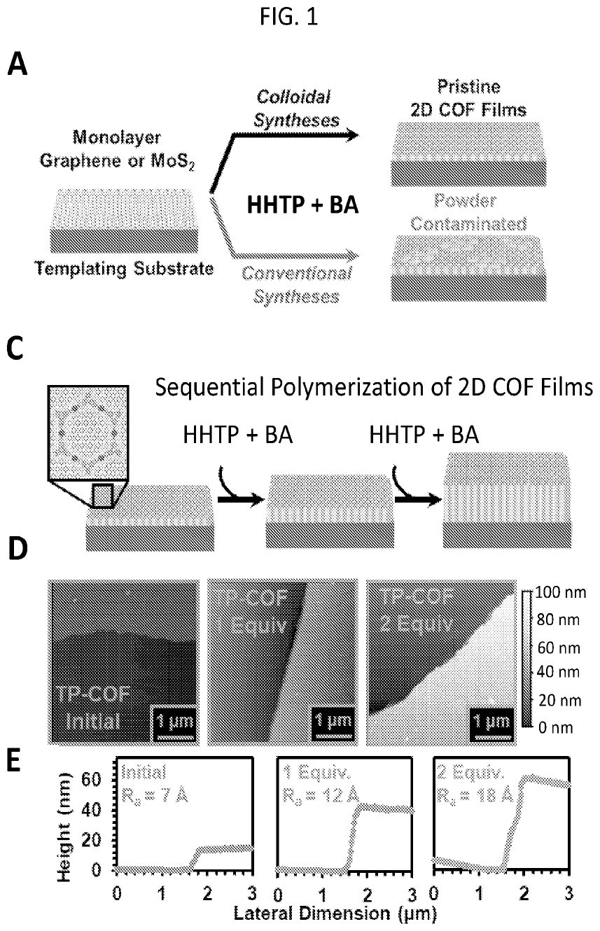

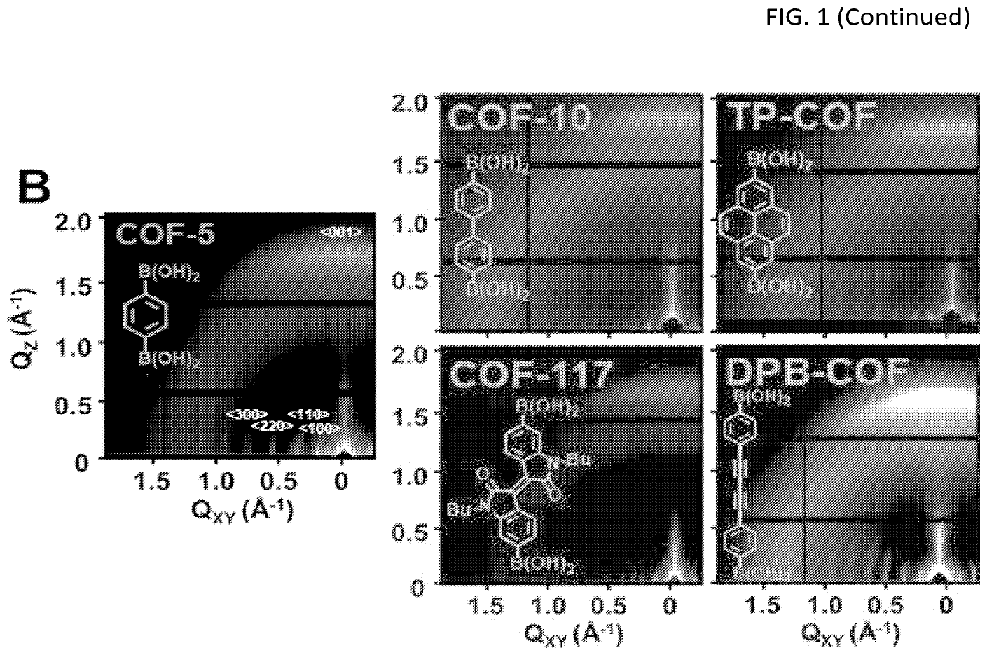

As demonstrated in the Examples, 2D COF films were polymerized directly by a templated colloidal approach. First, a templated substrate, such as SiO₂-supported graphene or an Al₂O₃-supported monolayer MoS₂, was contacted with a solution comprising a plurality of BUs and LUs, such as submerged into a solution of 2,3,6,7,10,11-hexahydroxytriphenylene (HHTP) and a difunctional aryl boronic acid (FIG. 1A, Schemes 4-8).

The polymerization mixtures were contacted with the templating substrate under conditions sufficient for preparing a COF. For example, the polymerization mixtures may be sealed and heated to 80° C. for 24 h. In some embodiments, the templating substrate is contacted with the solution at a temperature from 50° C. to 500° C., 50° C. to 400° C., 50° C. to 300° C., 50° C. to 200° C., 50° C. to 100° C., or any temperature therebetween. In some embodiments, the templating substrate is contacted with the solution at a temperature from 30 min to 1 month, 30 min to 1 week, 30 min to 72 h, 30 min to 48 h, or 30 min to 24 hr, or any time therebetween.

The COF deposited on the templated substrate may be removed from the reaction mixture, rinsed with clean solvent, and dried. The methods described herein result in an optically homogenous film across the entirety of the substrate.

To probe whether these films were being polymerized from solution or whether colloidal species were templating on the surface, a graphene-supported substrate was immersed in a prepolymerized colloidal 2D COF suspension and subjected to the polymerization conditions. No films form in the presence of prepolymerized reaction mixtures. Taken together, these observations suggest that homogenous nucleation occurs in solution and templated-heterogeneous nucleation occurs on the substrate simultaneously, which then polymerize independently.

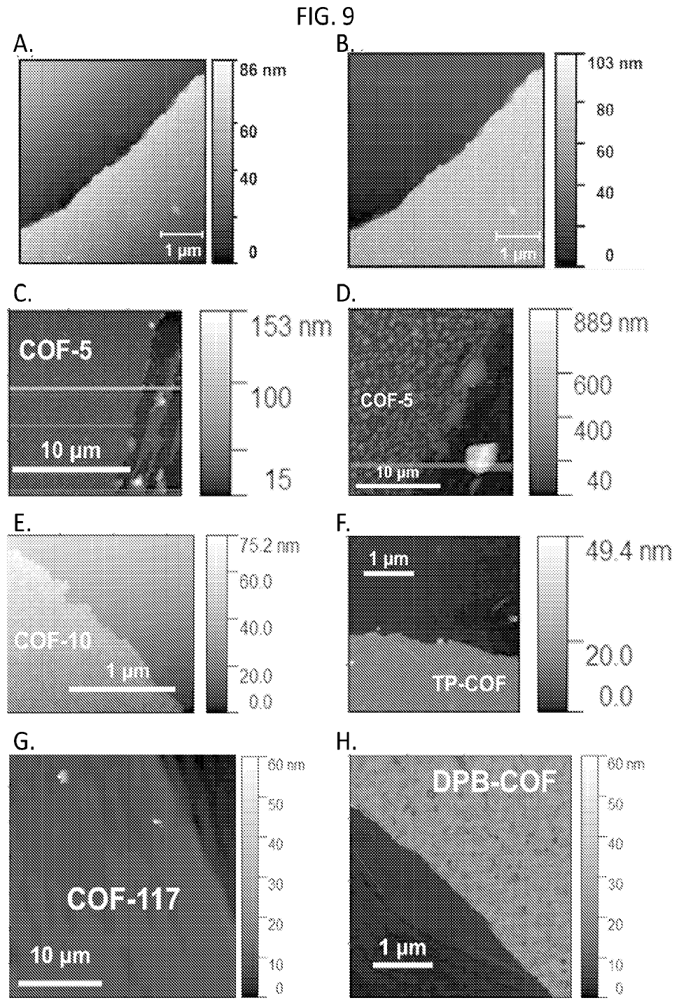

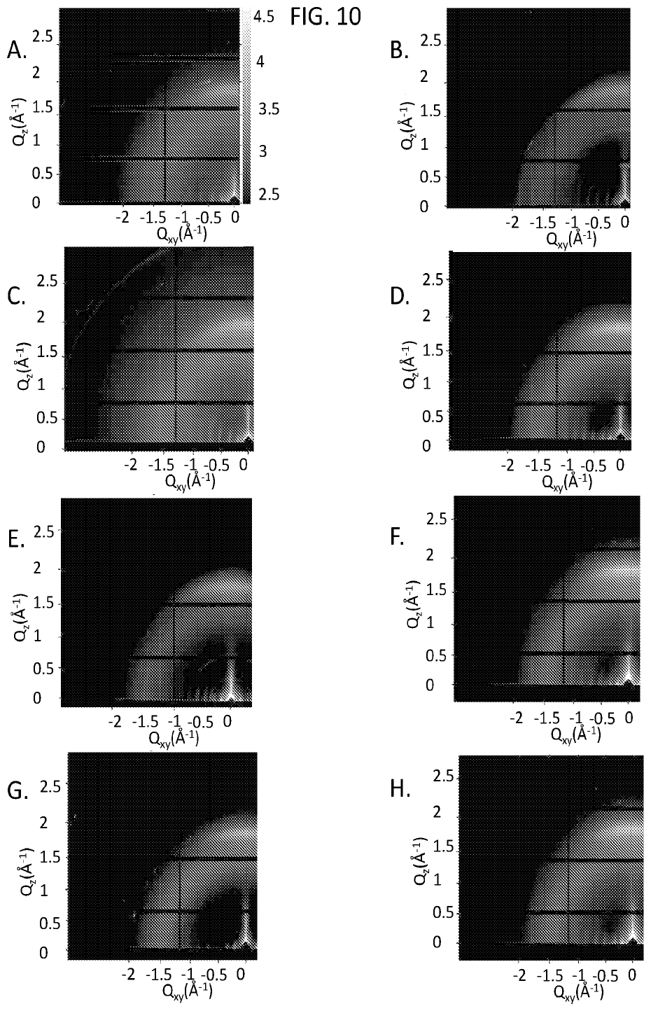

As demonstrated by the Examples, all COF films are found to be crystalline, oriented, and smooth. Atomic force microscopy (AFM) reveals that the materials are obtained as thin films (<75 nm) with <5 nm root-mean-square roughness in all cases (FIG. 9). 2D grazing-incidence wide-angle X-ray scattering (GI-WAXS) patterns of all COFs showed prominent in-plane Bragg diffraction features concentrated along the Q_{xy} axis and cross-plane Bragg features concentrated along the Q_{z} axis (FIG. 1B, FIG. 10), which show that 2D COF layers are oriented parallel to the substrate surface. By assessing the azimuthal dispersity of the interlayer <001> Bragg feature (˜2 Å⁻¹) intensity, we find that these films have a smaller full-width at half-maximum than those reported by other approaches. We attribute the weaker orientation of previously prepared films to the contamination by unoriented precipitates formed during their synthesis (FIG. 12). In all cases, radially integrated diffraction patterns were found to agree well with simulated COF diffraction patterns, confirming the successful synthesis of the expected COF networks (data not shown). The large number and sharp line shapes of diffraction features observed in these two patterns indicate that all COF films prepared by our colloidal method are highly crystalline. Thus, we find these films to be highly homogenous, crystalline, and oriented.

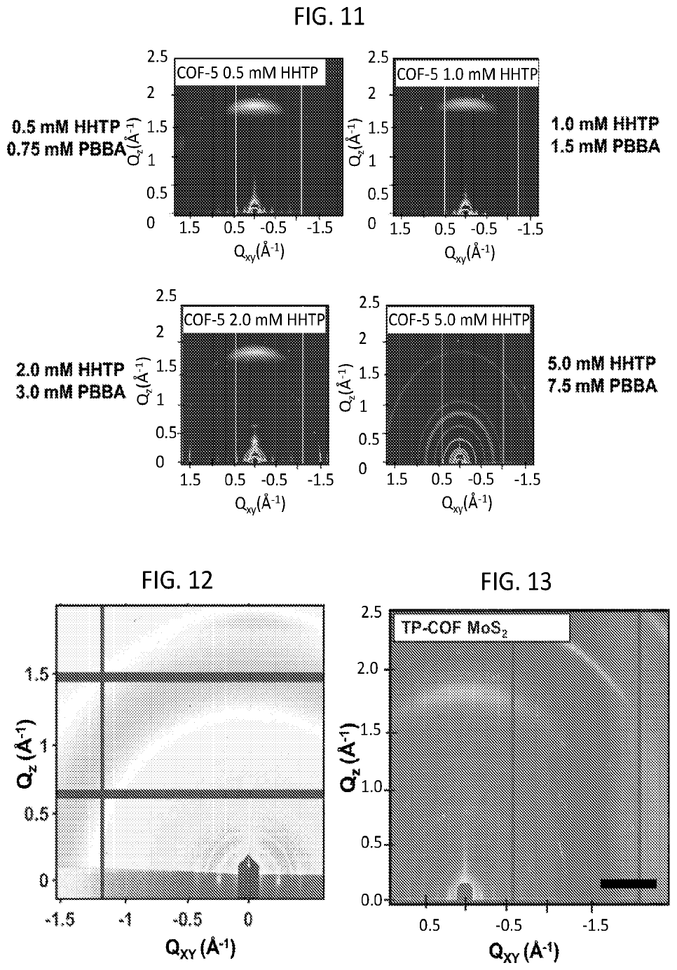

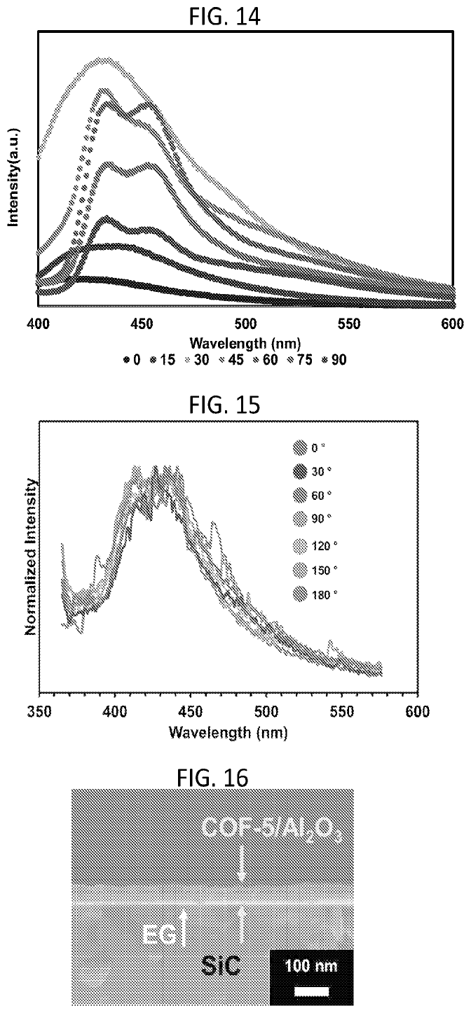

The high quality of these films allows for their repeated polymerization by the introduction of unreacted monomers (FIG. 1C). Typically, COF film thickness is controlled by modifying the starting monomer concentration used for their polymerization. However, when we attempted to polymerize COF-5 films with higher monomer concentrations, we found that resultant COF films, while thicker, were substantially less oriented and smooth (FIG. 11). This finding is consistent with observations of uncontrolled nucleation and growth at higher monomer concentrations^{22,25}. However, by polymerizing COF films using this templated growth approach, removing the substrate, immersing this substrate in a fresh monomer solution, and resubjecting it to the polymerization conditions, we can continue the polymerization of our films without a reduction in film quality. As an example, we sequentially increase the thickness of the TP-COF films from 20 nm, to 40 nm, to 60 nm over the course of three equivalent polymerizations (FIG. 1). In each sequential polymerization, we find that the roughness, crystallinity, and film orientation as evaluated by AFM and GI-WAXS do not discernably change (FIG. 10). Collectively, these observations demonstrate that templated colloidal polymerization offers a level of synthetic control not available in previously reported 2D polymerization strategies.

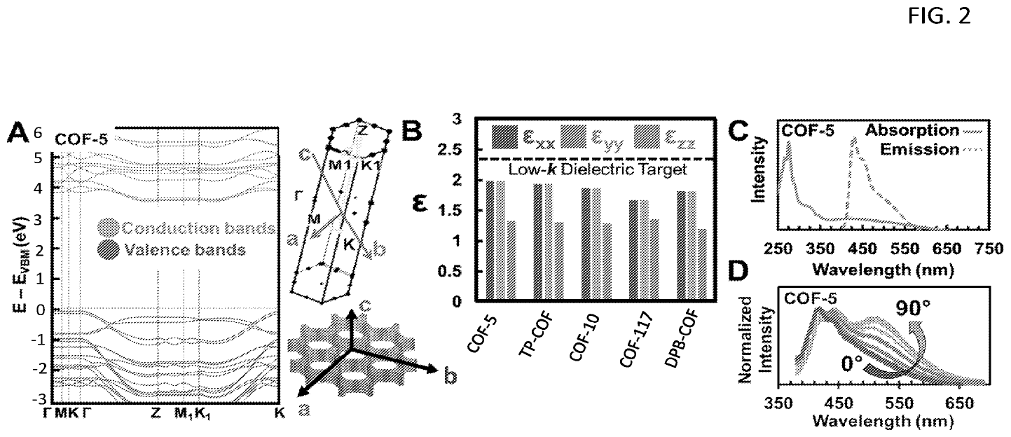

Boronate ester-linked 2D COF films studied here are sufficiently electrically insulating to serve as dielectric layers. DFT calculations using the PBE0 functional predict that COF-5 has an indirect bandgap of 3.6 eV and a direct gap of 3.9 eV (FIG. 2A). The DFT-calculated band structures have minimal band dispersion along the in-plane direction (Γ-M-K-Γ and Z-M₁-K₁) in both their valence and conduction bands, indicating low in-plane charge-carrier mobility. However, band dispersions of 0.4 eV along the out-of-plane direction in both the valence and conduction bands can be observed, which suggests that anisotropic charge transport may occur in COF-5 crystallites, as has been observed previously²². The DFT-calculated diagonal components of the static electronic dielectric tensors (εₓₓ, ε_{yy}, and ε_{zz}) are less than 2 for the five boronate ester-linked 2D COFs studied. As such, they are all candidate low-k dielectrics (FIG. 2B). We note that in COF-5 the ionic contribution to the total static dielectric tensor is calculated to be negligible (Table 3); thus, we only considered the electronic contribution to the dielectric tensor in the other four 2D COFs. Experimentally, we find that the first COF-5 optical absorption feature occurs at approximately 325 nm (3.8 eV), which is consistent with the predicted DFT bandgap (FIG. 2C). When the COF-5 structure is excited at 325 nm, we find that its emission profile is similar to monomeric HHTP, consistent with the limited electronic conjugation across boronate-ester bonds²⁶. Ultimately, these experimental and computational studies show that crystalline, 2D COF layers are electronically insulating and as pristine crystallites are promising as low-k dielectrics.

The pristine nature of the films prepared by colloidal syntheses permits the observation of their anisotropic optical emission. The polarization-dependent emission of a COF-5 film has a strong cross-plane emission feature at 530 nm, which has been assigned to the formation of triphenylene exciplexes (FIG. 2D). The observation of these cross-plane features suggests that the COF-5 films are highly oriented across the entirety of the sample. In contrast, polarization-dependent emission anisotropy is found to be far weaker in COF-5 films grown on the substrates under non-colloidal conditions (FIG. 15). This finding agrees with our understanding that previously obtained materials were likely contaminated with unoriented aggregates, which complicated their reliable measurement and subsequent integration into devices. Taken together, these measurements show that the COF films studied here are high quality.

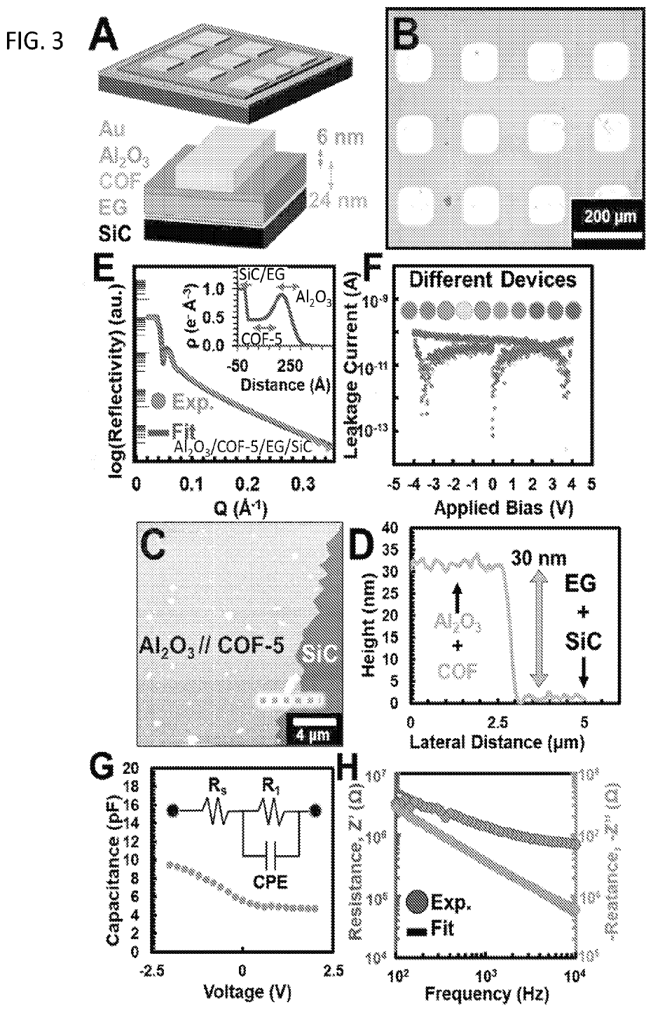

Impedance measurements conducted on parallel plate capacitors confirm that COF-5 is a low-k dielectric. First, we synthesized COF-5 thin films directly onto epitaxially grown graphene (EG) on doped SiC wafers. Next, a 6-nm-thick Al₂O₃ layer was deposited by atomic layer deposition to prevent shorting through the COF-5 pores before depositing top Au electrodes onto the Al₂O₃, which produced a series of devices over an area of 40 mm² (FIG. 3A and 3B). The thickness of the COF-5/Al₂O₃ bilayer (30 nm) was measured with AFM and cross-sectional scanning electron microscopy (FIG. 3C-3D and 16), which reveal the COF-5 layer is 24 nm thick. The integrity of COF-5/Al₂O₃ bilayer was confirmed by X-ray reflectivity (XRR) measurements (FIG. 3E) that showed well-resolved electron density profiles of the SiC, Al₂O₃, and COF-5 layers, which suggests that these layers do not substantially intermix (FIG. 3E, inset). This observation is consistent with a homogeneous COF-5 film over the entire wafer with minimal intercalation of Al₂O₃.

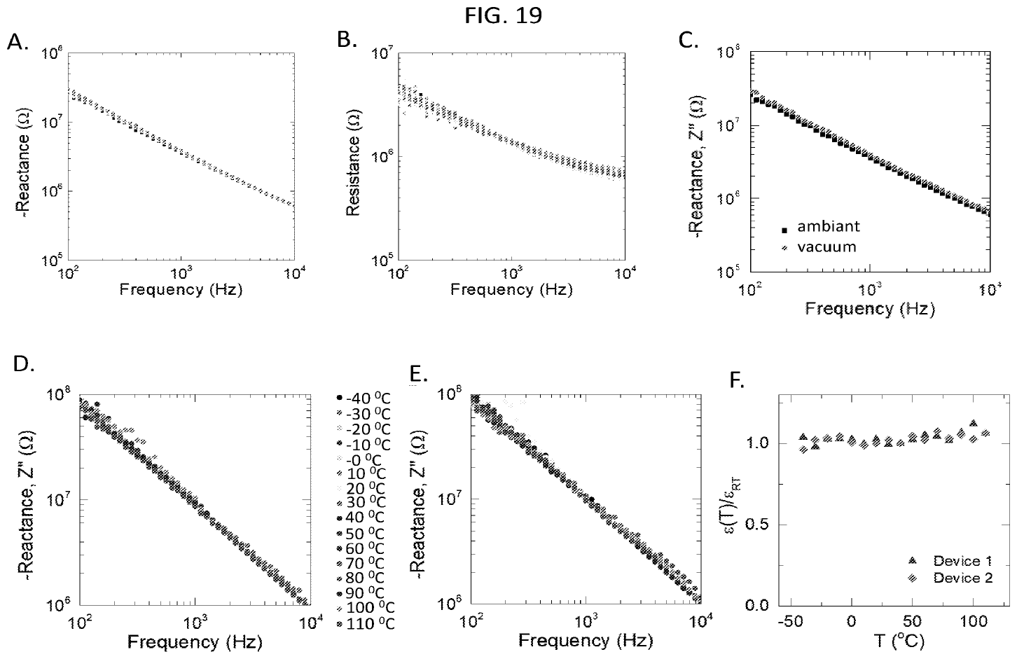

COF-5 capacitors show leakage current of less than 0.1 nA for applied bias range of −4 V to +4V (area 10⁴ μm², FIG. 3F), indicating robust dielectric layers. Effective capacitance was then extracted as ˜6 pF at 0 V, with bias-dependent capacitance attributed to the quantum capacitance of graphene (FIG. 3G). Next, we examined the frequency dependence of the real (resistance, Z′) and the imaginary (reactance, Z″) impedance (FIG. 3H), and fit this behavior as a simplified RC circuit (FIG. 3G, inset), with R₁ (10 GΩ) determined from leakage measurements and fitting Rₛ to account for series resistance (64 kΩ) from the SiC substrate and contacts. Finally, the non-ideal nature of the COF-5/Al₂O₃ bilayer is represented as the constant phase element (CPE) with a magnitude of 7.52±0.12 pF and an ideality factor of 0.9. Using the known thickness (6 nm) and dielectric constant of Al₂O₃ (k=6.5) and the total capacitance of the COF-5/Al₂O₃ bilayer (5.64 pF), the capacitance and dielectric constant of the COF-5 layers are extracted as 5.99 pF and 1.62, respectively. The excellent model fits and nearly ˜f⁻¹ behavior of reactance confirm the validity of the RC model (FIG. 3H). The capacitance was found to be uniform (within 10%) across the entire COF-5 film (FIG. 19A-19B), suggesting excellent uniformity of the thin film. This measured k is consistent with the DFT-calculated COF-5 dielectric tensors. We also observe that this ultra-low-k dielectric constant was invariant with respect to atmosphere composition and temperature (−40° C. −110° C., FIG. 19C-19E). Overall, these results show that thin, well-fabricated COF films function as low-k dielectric layers.

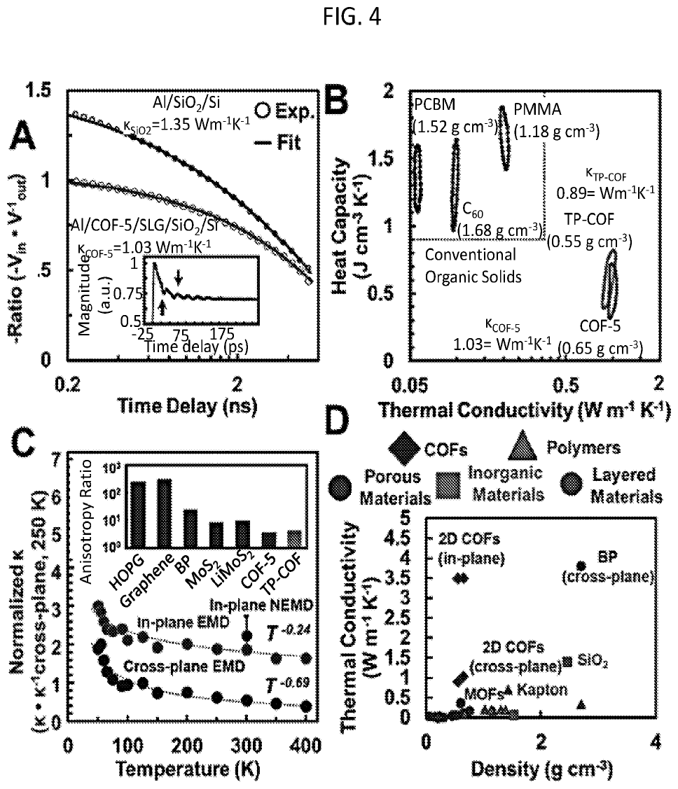

COF thin films are found to be substantially more thermally conductive than previously studied low-k dielectrics. To measure the thermal properties of COF thin films with time-domain thermoreflectance, we first deposited Al transducer layers onto several sub-100 nm thick COF films (FIG. 25). From TDTR measurements, we extract the COFs' longitudinal sound speeds, heat capacities, and cross-plane thermal conductivities (FIG. 4A and 4B). Fitted TDTR data revealed that COF-5 and TP-COF have volumetric heat capacities of C_{v,COF-5}=0.52±0.08 J cm⁻³ K⁻¹ and C_{v,TP-COF}=0.56±0.09 J cm⁻³ K⁻¹ and cross-plane thermal conductivities of κ_{COF-5}=1.03±0.15 W m⁻¹ K⁻¹ and κ_{TP-COF}=0.89±0.14 W m⁻¹ K⁻¹ within a 95% confidence interval, respectively (FIG. 4B). These values are corroborated with FDTR measurements performed independently (FIGS. 19-21). We also find that the interfacial thermal conductances across the COF/Al and COF/SLG interfaces are quite high (h_{K}>100 MW m⁻² K⁻¹; FIGS. 23-25), which highlights another advantage of COF films that are well-interfaced to their underlying substrate.

Compared to other organic or porous materials, 2D COFs have unusually high thermal conductivities. This finding is consistent with the structural regularity, large porosities, strong interlayer interactions, and low heat capacities unique to 2D COFs. From picosecond acoustics, we determine sound speeds for COF-5 (FIG. 4A, inset) and TP-COF to be 2000±300 m s⁻¹ and 1900±300 m s⁻¹, respectively. These sound speeds are higher than those recently observed in MOFs (e.g. MOF-5: 1184 m s⁻¹) despite similar porosity to the two COF's studied here.^{28,29} These relatively high thermal conductivities and longitudinal sound speeds (as compared to other porous materials) demonstrate how unique thermal properties arise from COF's covalently linked, layered, precisely porous structures.

Molecular dynamics (MD) simulations give additional insight into COF-5's high anisotropic thermal conductivities. The MD-predicted cross-plane thermal conductivities are slightly lower than the measured values, which could be a consequence of the insufficiencies of the interatomic potential used to model our 2D COFs. However, these differences are equivalent in all crystallographic directions and so, through the same analysis, we extract an anisotropy ratio of 3.4 between in-plane and cross-plane COF-5 thermal conductivities (FIG. 4C). This anisotropy is valuable for thermally dissipative coatings, including in low-k dielectric layers, where device failure from thermal buildup can be mitigated. By this approach, we predict that the in-plane κ_{COF-5}=3.5 W m⁻¹ K⁻¹. These absolute thermal conductivities and anisotropy ratios are lower for 2D COFs than other layered crystals (FIG. 4C, inset), which likely arises as a function of periodic voids in their van der Waals surface. The temperature dependent thermal conductivities of COF-5 in the range of 50 K-400 K are shown to exhibit a T^{-0.24} and T^{-0.69} dependence in the in-plane and cross-plane directions, respectively (FIG. 4C). These temperature dependencies suggest that anharmonic processes dictate the thermal transport in the cross-plane direction more heavily than the in-plane direction³⁰.

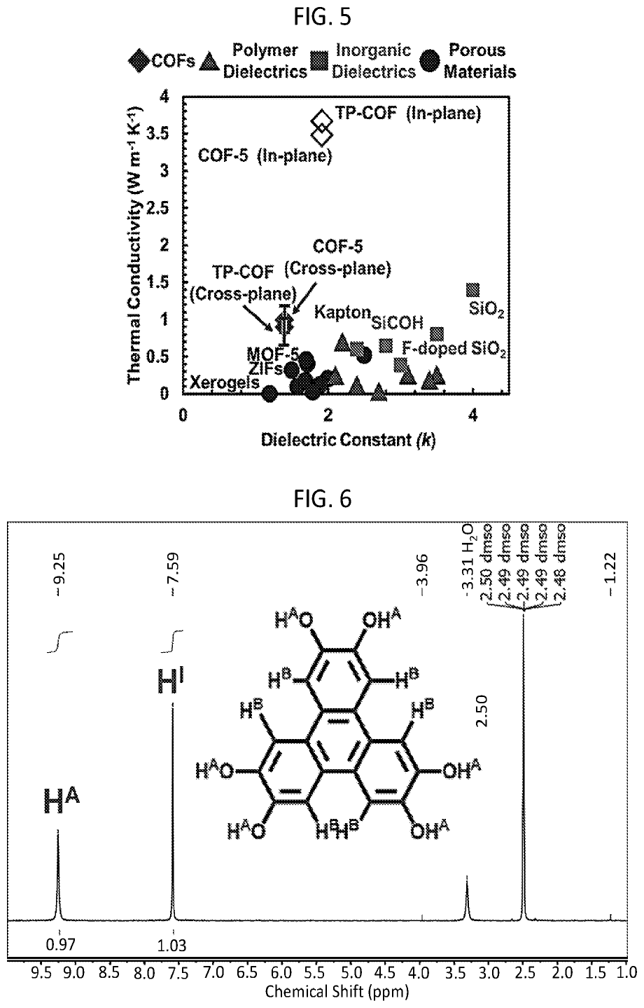

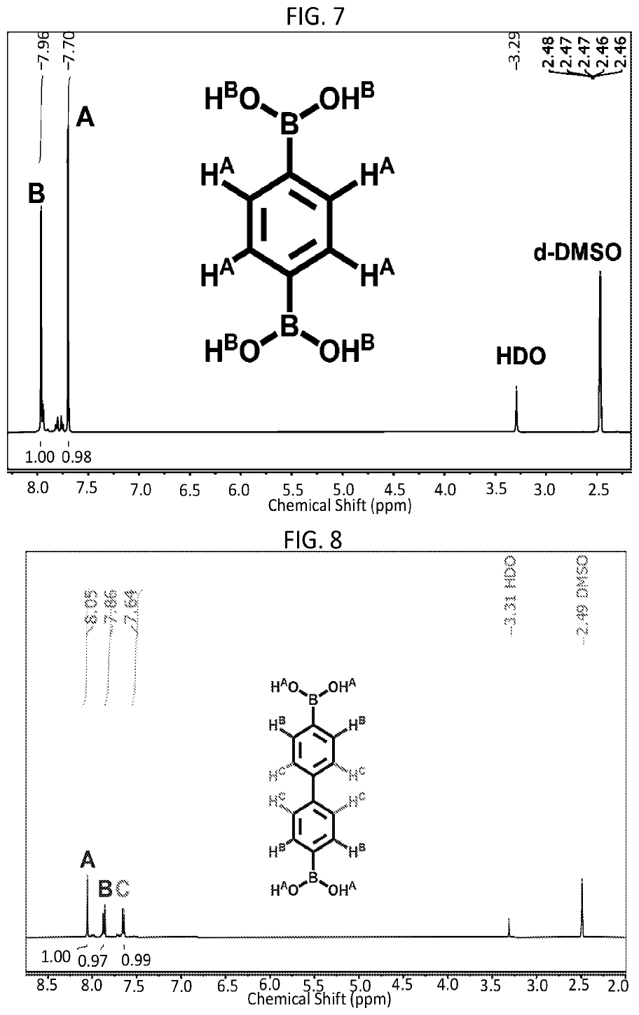

2D COFs overcome the traditional tradeoff between dielectric permittivity and thermal conductivity found in all known low-k dielectric materials (FIG. 5). For example, dense amorphous metal oxides such as Al₂O₃ or HfO₂ are relatively thermally conductive compared to low-density aerogels, which are thermally insulating due to their porous structure and tortuous solid networks^{8,31,32}. Although the densities of 2D COFs are comparable to those of aerogels, their thermal conductivities are comparable to those of materials that are an order of magnitude more dense, such as conventional amorphous metal oxide dielectrics³². This uniquely high thermal conductivity is most likely driven by the well-interfaced van der Waals contact of porous 2D polymers that are arranged as eclipsed stacks. Based on additional molecular dynamics simulations performed on other boron-based 2D COFs (data not shown), we find that the thermal conductivity of these systems is correlated to their van der Waals interactions and inversely related to their porosity. This suggests that smaller pore COFs with large van der Waals surfaces will be highly thermally conductive. Furthermore, we suspect that the thermomechanical properties of 2D COFs could be modulated by the introduction of molecular guests, as has been observed in other porous materials, which unlocks the possibility of responsive materials^{33,34}. Taken together, 2D COFs mark a new regime of materials design that combines low densities with high thermal conductivities. The combined thermal resistances of these COF films (including both thermal conductivity and thermal boundary conductances) highlight 2D COFs as low thermal resistance, ultra-low-k thin films relative to traditionally studied low-k dielectrics.

In conclusion, we find that 2D COFs unique combination of structural, thermal, and electronic properties make them promising as low-k dielectric layers. Through a templated colloidal synthetic approach, we access smooth COF thin-film dielectrics of tailorable thickness on technologically relevant substrates. Through our experimental and computational investigations, we find that boronate ester-linked 2D COFs are electronically insulating, consistent with their lack of long-range conjugation, and are low-k dielectrics, consistent with their permanent porosities. We also find that 2D COFs exhibit unusually high thermal conductivities for low density, low-k dielectrics, a combination of properties that was recently identified by the International Roadmap for Semiconductors as a necessary materials development for next-generation integrated circuits. Taken together, these results demonstrate that exotic combinations of properties can be unlocked by using synthetic chemistry to generate precise materials.

### Miscellaneous

Unless otherwise specified or indicated by context, the terms “a”, “an”, and “the” mean “one or more.” For example, “a molecule” should be interpreted to mean “one or more molecules.”

As used herein, “about”, “approximately,” “substantially,” and “significantly” will be understood by persons of ordinary skill in the art and will vary to some extent on the context in which they are used. If there are uses of the term which are not clear to persons of ordinary skill in the art given the context in which it is used, “about” and “approximately” will mean plus or minus ≤10% of the particular term and “substantially” and “significantly” will mean plus or minus >10% of the particular term.

As used herein, the terms “include” and “including” have the same meaning as the terms “comprise” and “comprising.” The terms “comprise” and “comprising” should be interpreted as being “open” transitional terms that permit the inclusion of additional components further to those components recited in the claims. The terms “consist” and “consisting of” should be interpreted as being “closed” transitional terms that do not permit the inclusion additional components other than the components recited in the claims. The term “consisting essentially of” should be interpreted to be partially closed and allowing the inclusion only of additional components that do not fundamentally alter the nature of the claimed subject matter.

All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

All references, including publications, patent applications, and patents, cited herein are hereby incorporated by reference to the same extent as if each reference were individually and specifically indicated to be incorporated by reference and were set forth in its entirety herein.

Preferred aspects of this invention are described herein, including the best mode known to the inventors for carrying out the invention. Variations of those preferred aspects may become apparent to those of ordinary skill in the art upon reading the foregoing description. The inventors expect a person having ordinary skill in the art to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

### EXAMPLES

### Grazing-Incidence X-ray Diffractions

GIWAXS measurements were performed at either:

Advanced Photon Source at Argonne National Laboratory using the 8-ID-E Beamline under vacuum. All measurements were conducted with an incidence angle of 0.14° using 10.92 keV (λ=1.135 Å) X-rays. The scattered photons were recorded on a Pilatus 1 M detector located 228 mm from the sample. Exposure times were varied such that the pixel with maximum counts was at 80% of saturation. In some cases, significant silicon substrate scatter was observed. The raw images were merged, pixel coordinates were transformed to q-space, and line cuts were generated using GIXSGUI for Matlab.¹

or

Advanced Light Source-Lawrence Berkeley National Laboratory using Beamline Station 7.3.3 under a He atmosphere. A photon energy of 10 keV (λ=1.24 Å). Data was collected by a Pilatus 2M detector with a pixel size of 0.172×0.172 mm and 1475×1679 pixels used to capture the 2D scattering patterns at a distance of 300 mm from the sample. A silver behenate standard was used as a calibrant. The grazing angle, α, was varied from 0.08° to 0.25°. Data were analyzed using the Nika macro for Igor Pro.²

All data is shown as a function of the scattering vector:

$$Q = \frac{4 π}{λ} sin ( θ ) \qquad ( 1 )$$

### Density Functional Theory

The electronic band structures of COF-5 were calculated with the CRYSTAL17 package^{8,9} at the DFT PBEO level^{10,11} using the POB-TZVF basis set with D3 van der Waals (vdW) corrections¹². 2×2×14 and 2×2×18Γ-centered Monkhorst-Pack k-meshes were adopted in the geometry optimizations and self-consistent calculations (SCF), respectively.

The macroscopic static dielectric tensors taking account of the electronic contributions¹³ were calculated at the DFT PBE level using the Vienna Ab initio Simulation Package (VASP)¹⁴ and D3 vdW corrections. Γ-centered Monkhorst-Pack k-meshes were adopted in both geometry optimizations and SCF calculations (see Table 1). The convergence criterion for the total energy was set at 10⁻⁸ eV; the one for the forces was set at 0.01 eV Å⁻¹. We considered a Gaussian smearing of 0.01 eV. The lattice parameters after geometry optimization of each COF are shown in Table 2. The off-diagonal components in the calculated macroscopic static dielectric tensors are vanishingly small. The ionic contributions to the macroscopic static dielectric tensors of COF-5 were calculated via density functional perturbation theory (DFPT)¹⁵ using VASP (Table 3).

TABLE 1
Γ-centered Monkhorst-Pack k-meshes applied in
the DFT/PBE calculations for the five COFs.
Γ-centered Monkhorst-Pack k-meshes applied for each COF

| | COF-5 | TP-COF | COF-10 | COF-117 | DPB-COF |
|---|---|---|---|---|---|
| Optimization | 1 × 1 × 8 | 1 × 1 × 10 | 1 × 1 × 10 | 1 × 1 × 11 | 1 × 1 × 12 |
| SCF | 2 × 2 × 16 | 2 × 2 × 20 | 2 × 2 × 20 | 2 × 2 × 22 | 2 × 2 × 24 |

TABLE 2
Optimized crystal structures at the
DFT/PBE level for the five COFs.

| | a(Å) | b(Å) | c(Å) | α(°) | β(°) | γ(°) |
|---|---|---|---|---|---|---|
| COF-5 | 30.17 | 30.17 | 3.73 | 90.00 | 90.00 | 120.00 |
| TP-COF | 37.53 | 37.53 | 3.72 | 90.00 | 90.00 | 120.00 |
| COF-10 | 37.72 | 37.72 | 3.71 | 90.00 | 90.00 | 120.00 |
| COF-117 | 41.98 | 41.98 | 4.08 | 90.00 | 90.00 | 120.02 |
| DPB-COF | 46.53 | 46.53 | 3.74 | 90.00 | 90.00 | 120.00 |

TABLE 3
Ionic and electronic contributions to the
COF-5 dielectric tensors.

| | εₓₓ | ε_{yy} | ε_{zz} |
|---|---|---|---|
| Ionic contributions | 0.3 | 0.1 | 0.0 |
| Electronic contribution | 2.0 | 2.0 | 1.3 |
| Total | 2.3 | 2.1 | 1.4 |

### Fluorescence Spectroscopy

Emission and excitation spectra were recorded on a Horiba Jobin Yvon Fluorolog-3 fluorescence spectrophotometer equipped with a 450 W Xe lamp, emission and excitation polarizer, double excitation and double emission monochromators, a digital photon-counting photomultiplier and a secondary InGaAs detector for the NIR range. Correction for variations in lamp intensity over time and wavelength was achieved using a solid-state silicon photodiode as the reference. The spectra were further corrected for variations in photomultiplier response over wavelength and for the path difference between the sample and the reference by multiplication with emission correction curves generated on the instrument. To collect emission spectra of the 2D COF films, films were mounted in a proprietary film holder. When emission polarization was noted as “normalized”, we divided the intensity of all emission intensities by the maximum emission intensity.

### Device Measurement

Impedance measurements were carried out by a Solartron 1260 impedance analyzer using an AC amplitude of 100 mV in a frequency range of 100 Hz to 10 kHz. This frequency range was chosen because the signal was too noisy below 100 Hz and series resistance from the SiC wafer interfered with measurements above 10 kHz. Au pads were contacted by tungsten cat whisker soft-probes (Signatone, SE-SM) to avoid puncturing the COF dielectric. Capacitance-frequency (C-f) measurements were performed at zero dc bias, and capacitance-voltage (C-V) measurements were conducted at 1 kHz. Capacitance values were verified independently using the C-V module of a 4200 Semiconductor Characterization System (SC S), Keithley Instruments. Leakage measurements were also carried by the 4200 SCS system using a remote current preamplifier. Impedance data was analyzed by model fitting using ZPlot/ZView software from Scribner Associates, Inc.

### Heat Capacity and Thermal Conductivity Measurements

In our time-domain thermoreflectance (TDTR) setup, sub-picosecond laser pulses emanate from a Ti:Saphhire oscillator at 80 MHz repetition rate. The pulses are separated into a pump path that heats up the sample and a time-delayed probe path that is reflected from the Al transducer. The reflected probe beam provides a measure of the change in the thermoreflectance due to the decay of the thermal energy deposited by the pump beam. A modulation of 8.8 MHz is applied by an electro-optic modulator on the pump beam and the ratio of the in-phase to out-of-phase signal of the reflected probe beam recorded at that frequency by a lock-in amplifier (−Vᵢₙ/Vₒᵤₜ) for up to 5.5 ns after the initial heating event. The pump and probe beams are focused on to the Al transducer at 1/e² radii values of 10 and 5 μm, respectively. To simultaneously measure the thermal conductivity and heat capacity of our COFs, we fit a three-layer thermal model to our experimental data. We also perform FDTR measurements on our COF-5 sample. Similar to TDTR, FDTR is also a laser-based metrology implemented to measure thermal properties of a sample. The Au-coated sample is periodically heated via a sinusoidally modulated (100 kHz-5 MHz) pump laser at 488 nm wavelength. The sample's temperature will fluctuate with the same frequency as the pump laser, but with a time delay. This phase delay is characteristic of the thermal properties of the sample. The temperature is measured using a concentric probe laser (532 nm), which is sensitive to the thermoreflectance of Au. The frequency-dependent time delay measured as a phase delay of the reflected probe laser with respect to the pump laser modulation frequency is measured with a photodiode connected to a lock-in amplifier.

### MD Simulation

Our molecular dynamics (MD) simulations are performed with the LAMMPS code²² and the interatomic interactions are described by the adaptive intermolecular reactive empirical bond order (AIREBO) potentia1. 23 We apply periodic boundary conditions in all directions. The computational domains are equilibrated under the Nose-Hoover thermostat and barostat,²⁴ (which is the NPT83 integration with the number of particles, pressure and temperature of the system held constant) for a total of 1 ns at 0 bar pressure. Following the NPT integration, an NVT integration (with constant volume and number of particles) is prescribed to fully equilibrate the structures at the desired temperature for another 1 ns. Note, we prescribe a time step of 0.5 fs for all our simulations. For the simulations, we vary the total cross-plane thickness, d, and length of the computational domain, L, to check for size effects in our thermal conductivity predictions as detailed below.

After equilibration, the thermal conductivities of our COFs at different temperatures predicted via the Green-Kubo (GK) approach under the EMD framework. In this formalism, the thermal conductivities of our COFs along the x-,y-(in-plane) and z-(cross-plane) directions are calculated as,

$${κ}_{x , y , z} = \frac{1}{{k}_{B} V {T}^{2}} {\int }_{0}^{∞} < {S}_{x , y , z} ( t ) \cdot {S}_{x , y , z} ( 0 ) > d t \qquad ( 2 )$$

Here t is time, T and V are the temperature and volume of the systems, respectively, and <S_{s,t,z}(t) S_{x,y,z}(0)>is the component of the heat current autocorrelation function (HCACF) in the prescribed directions.

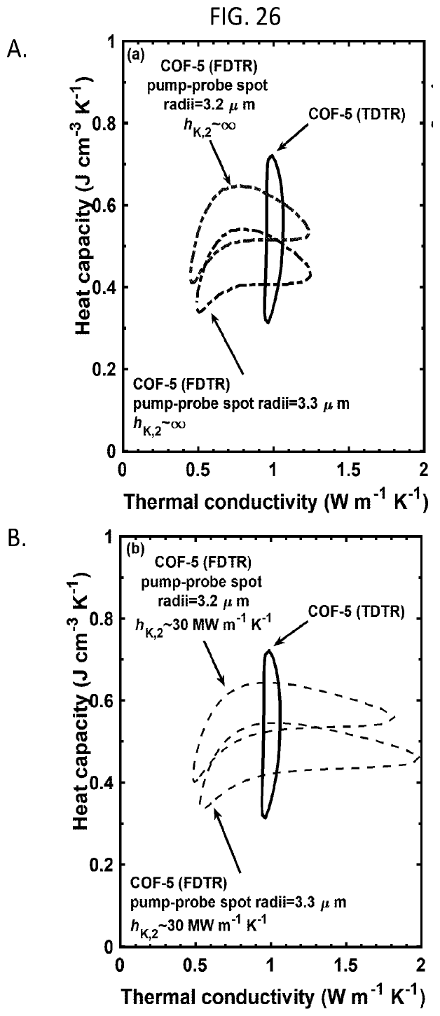

To ensure that the HCACF decays to zero, we set the total correlation time period for the integration of the HCACF to 50 ps as shown in the inset of FIG. 23. The heat current is computed every 10 time steps during the data collection period, after which, integration is carried out to calculate the converged thermal conductivity for our COF-5 structure. The converged thermal conductivity is determined by averaging from 10 ps to 50 ps as shown in FIG. 26 (dashed line). We note that since the main goal of our simulations is to establish a comparative analysis of in-plane and cross-plane thermal conductivity, we refrain from comparing our experimentally determined cross-plane thermal conductivity with our MD predictions. Moreover, the choice of the interatomic potential has large implications on the thermal conductivity predictions for similar covalently bonded carbon structures.²⁵⁻²⁷

The GK approach has been extensively used to predict the lattice thermal conductivity of different crystalline and amorphous material systems. However, there has been considerable ambiguity in efficiently calculating the thermal conductivity via Eq. 2 due to uncertainties associated with finite simulation times and domain sizes. To ensure that the EMD-predicted thermal conductivities are not influenced by size effects, the dimensions of the simulation box are chosen to produce converged values of thermal conductivities. To this end, the thermal conductivities of structures with cross-sections of 15×13 nm² and 30×26 nm² are comparable within uncertainties. Similarly, the thermal conductivities of structures with computational domain sizes of 15.1×13.1×3.4 nm³, and 15.1×13.1×10.2 nm³ are also similar within uncertainties.

Since there has been contention on the use of the heat current calculations in LAMMPS to predict the thermal conductivity of structures with many-body interatomic potentials, we run nonequilibrium MD (NEMD) simulations to gain more confidence in our in-plane thermal conductivity predictions for our COF-5 structure. For the NEMD simulations, a steady-state temperature gradient is established by adding a fixed amount of energy per time step to a heat bath at one end of the computational domain, while removing an equal amount of heat from a cold bath at the other end of the domain; energy is added and removed at specified rate of 0.4 eV ps⁻¹ under the microcanonical ensemble where the number of atoms (N), volume (V), and energy (E) of the system are held constant. A fixed wall at either side of the domain is enforced for our NEMD simulations. The temperature profile along the in-plane direction is obtained by averaging the temperature of the atoms along equally spaced bins in the applied heat flux direction for a total of 10 ns and the thermal conductivity is predicted via Fourier's law; the initial 3 ns of data are ignored to create time-averaged steady-state temperature profiles. We calculate thermal conductivities for different domain lengths to accurately predict the bulk in-plane thermal conductivity of our COF-5 structure. For this, we plot the inverse of thermal conductivity, κ⁻¹, as a function of the inverse of the computational domain length, d⁻¹, which shows a linear trend as shown in FIG. 24, and extrapolate to d⁻¹=0 to predict the size-independent thermal conductivity. The result of the NEMD simulations and EMD simulations are shown in FIG. 4C of the manuscript. Our EMD simulations underpredict the cross-plane thermal conductivity of COF-5, which could potentially be due to the insufficiencies in the interatomic potential used to describe the COF structures. However, the fact that our experimental measurements are higher in comparison to the defect-free pristine structures simulated in our MD calculations, exemplifies the high quality of our crystalline 2D COFs studied in this work. From our EMD and NEMD simulations, we predict an in-plane thermal conductivity of ˜2 W m⁻¹ K⁻¹ and an anisotropy ratio of ˜4 between the in-plane and cross-plane thermal conductivity predictions.

To get an estimate for the heat capacity of these COFs, we calculate the vibrational density of states (DOS) from our MD simulations. The velocities of the atoms in the COF-5 structure are output every 10 time steps for a total of 1 ns. A velocity autocorrelation function algorithm is used to obtain the local phonon DOS in the cross-plane and in-plane directions as shown in FIG. 25. The density of states, D(ω), is obtained from the Fourier transform (F) of the velocity correlation function (VACF). The Welch method of power spectral density estimation is applied to obtain the D(ω) and is normalized as follows,

$$D ( ω ) = \frac{1}{2} m ℱ ( V A C F ) ( \frac{1}{{k}_{B} T} ρ ) \qquad ( 3 )$$

where m is the atomic mass, k_{B} is the Boltzmann constant, T is the local temperature, and ρ is the atomic density. We use the DOS to calculate the room temperature heat capacity as,

$${C}_{V} = {\int }_{0}^{{ω}_{c}} h ω D ( ω ) \frac{d f}{d T} d ω \qquad ( 4 )$$

where ω_{c} is the cutoff frequency, and f is the Bose-Einstein distribution. We estimate a value of Cᵥ˜0.54 J cm⁻³ K⁻¹ for our COF-5 at room temperature, which agrees well with our experimentally determined value (Cᵥ˜0.52±0.08 J cm⁻³ K⁻¹).

To generalize our results and to investigate the effect of varying porosities on the thermal conductivity of 2D COFs, we perform additional GK simulations on structures with varying densities in the range of 0.5 g cm⁻³ to 1 g cm⁻³. The structures compared are based on TP-COF, COF-5, and COF-1 (with pore sizes of ˜3.6 nm, 2.7 nm and 1.3 nm, respectively). To investigate the effect of varying porosities while maintaining similar internal microstructure, we modify the COF-1 structure by adding a phenyl ring to the linkers (COF-1-2R, where ‘R’ stands for ‘rings’). We compare the thermal conductivity of these four different 2D COFs with varying porosities and internal architectures in the zig-zag, arm-chair and cross-plane directions as a function of their densities. The thermal conductivity in the zig-zag and arm-chair directions are similar within uncertainties for a particular COF. More interestingly, the thermal conductivity of 2D COFs is significantly dictated by their corresponding density, both in the in-plane and cross-plane directions. These additional simulations provide design criteria for the synthesis of 2D COFs with potentially modular thermal conductivities based on controlling their porosity.

### X-ray Reflectivity

XRR measurements were carried out using a Rigaku ATXG diffractometer equipped with an 18 kW Cu rotating anode (λ=1.5418 Å) operating at a voltage of 50 kV and a current of 240 mA, with a collimated beam of 0.1 mm×2 mm (0.2 mm²). All measurements are plotted in terms of the scattering vector Q, normalized to the measured incident beam intensity, and corrected for geometrical footprint and background signal. The XRR analysis was performed using Motofit software. 3 Three different systems were studied: COF-5/EG/SiC, COF-5/EG/SiO₂/Si and Al₂O₃/COF-5/EG/SiO₂/Si. The fittings show a well-resolved electron density profile which confirms no intermixing or degradation of the COF-5 film. All the electron densities correspond to the expected bulk-like values. The electron density for the COF-5 film was a free parameter determined from the fit. The fitting parameters are included in Tables 4-6. The fit determined electron density profiles are shown as insets in each of the XRR figures.

### Atomic Force Microscopy

Atomic force microscopy (AFM) was conducted using the facilities at the Northwestern Atomic and Nanoscale Characterization Experiment Center (NUANCE) on a SPID Bruker FastScan AFM using a gold tip under the non-contact mode in air. To prepare films for imaging, they were scored with a pair of Teflon-coated forceps so as to not damage the underlying Si. These films were then imaged across the score to evaluate their thickness and roughness.

### Scanning Electron Microscopy

2D COF films were cleaved and mounted with carbon tape or double-sided copper taper on vertical SEM mounts. Each sample was coated with 7 nm of Os (SPI Osmium Coater, with OsO₄ as a volatile source) to create a conformal conductive coating prior to imaging. Images were collected with a Hitachi SU 8030 scanning electron microscope with an acceleration voltage of 5 kV at a magnification of 80,000.

### Preparation of Epitaxial Graphene on SiC

Epitaxial graphene was grown on 4H-SiC(0001) wafers (Cree, Inc.) by ultra-high vacuum (UHV) annealing. The SiC wafers were diced into 5×9 mm rectangles (American Precision Dicing, Inc.) and the resulting substrates were first degreased via sonication in acetone and isopropanol before being introduced into the UHV chamber with base pressure ˜5·10⁻¹¹ Torr. Substrates were degassed for 12 hours at 500° C. prior to graphitization at 1200° C. for 20 minutes while maintaining chamber pressure below 5·10′ Torr. During annealing, substrate temperature was monitored using an infrared pyrometer (ε=0.85).

### Nuclear Magnetic Resonance

¹H NMR spectra were acquired on a 400 MHz Agilent DD MR-400 system or Bruker Avance III 500 MHz spectrometer and recorded at 25° C. All chemical shifts were calibrated using residual solvent as internal reference (CDCl₃: 7.26 ppm for ¹H NMR. DMSO: 2.5 ppm for ¹H NMR).

### Capacitor Fabrication and Characterization

First, atomic layer deposition (ALD) was used to grow Al₂O₃ on COF-coated EG-SiC substrates using a Savannah S100 ALD reactor (Cambridge Nanotech, Cambridge MA). The substrates were loaded into the chamber pre-heated to 100° C. The base pressure of the chamber was maintained at 0.8 Torr with a constant N2 flow rate of 20 sccm. The growth was done at 100° C. by exposing samples to sequential doses of the metal oxide precursor (trimethyl aluminum (TMA), Aldrich, 99%) and deionized water interspersed with dry N2 purge steps between each precursor dose. For Al₂O₃ growth, a single ALD cycle consisted of a TMA pulse for 0.015 s and a 30 s purge, followed by a H₂O pulse for 0.015 s and a second 30 s purge. During growth, TMA precursor bottles were kept at room temperature. An approximately 6-nm-thick Al₂O₃ was grown on COF layer by using 75 pulses of TMA using 0.8 Å/cycle growth rate, as verified independently for atomic force microscopy and ellipsometry. The thickness of Al₂O₃/COF-5 dielectric bilayer was extracted from topography images (FIG. 3C-D) using tapping mode in an Asylum Cypher AFM system.

Parallel plate capacitors were completed by growing 100-nm-thick Au films on Al₂O₃/COF-5 dielectric bilayer using a thermal evaporator (Nano38, Kurt J. Lesker Company). The evaporation was done through a shadow mask with rectangular holes of 100 μm×100 μm using a growth rate of 1 Å/sec.

### Monomer Synthetic Procedures

All monomers, solvents, and catalysts were either purchased from commercial sources or prepared following literature reported protocols. All materials were used as received without further purification, including 2,3,6,7,10,11-Hexahydroxytriphenylene Hydrate (HHTP) (TCI America), 1,4-phenylenebisboronic acid (PBBA) (Sigma Aldrich), and 4,4′-biphenylbisboronic acid (BBBA) (Sigma Aldrich). Anhydrous THF was obtained from a solvent purification system (JC Myer System).

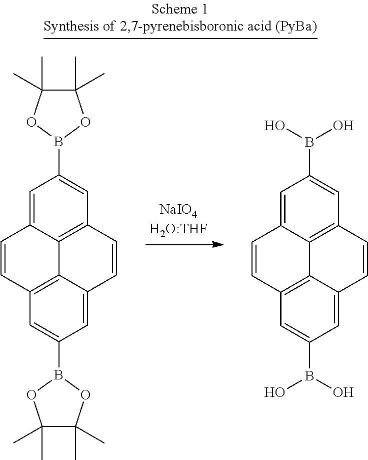 [SMILES: CC1(C)OB(c2cc3ccc4cc(B5OC(C)(C)C(C)(C)O5)cc5ccc(c2)c3c45)OC1(C)C ; OB(O)c1cc2ccc3cc(B(O)O)cc4ccc(c1)c2c34]

Synthesis of 2,7-pyrenebisboronic acid. PyBA was prepared by an adaptation of a previously reported synthesis.⁴ A THF:H20 mixture (300 mL, 4:1 vol) of pyrene-2,7-diboronicester (5g, 11 mmol, 1.0 equiv.) and NaIO₄ (3.5 g, 27.5 mmol, 2.5 equiv.) was prepared in a 500 mL RBF and stirred at room temperature for 16 hrs under N². During the course of this reaction, a white precipitate was formed. The reaction mixture was then diluted with H₂O (300 mL) and filtered. During filtration, the product was washed with an additional 300 mL of H₂O, taking care to not allow the product to dry completely on the filter paper. The product was then flushed with hexanes and dried, which produced a white powder (2.6 g, 81%). ¹H NMR analysis of this product was consistent with a previous report.⁴ ¹H NMR (400 MHz, DMSO-d₆, 298 K): δ ppm 8.68 (4H, s, 1,3,6,7-H-pyrene), 8.44 (4H, s, 4,5,9,10-H-pyrene), 8.16 (4H, s, BO-H)

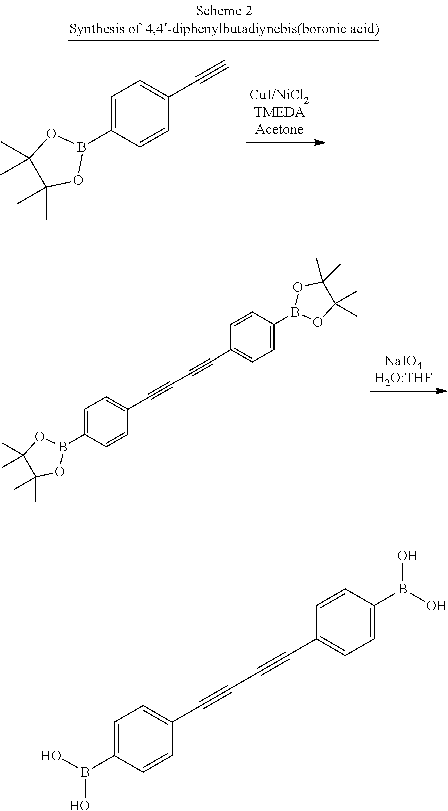

Synthesis of 4,4′-diphenylbutadiynebis(pinacolborane). The synthesis of this product was adapted from a previous report.⁵ A 100 mL round bottom flask was charged with CuI (0.752 g, 3.94 mmol, 0.05 equiv.), NiCl₂⋅ 6H₂O (0.936 g, 3.94 mmol, 0.05 equiv.), and tetramethylethylenediamine (TMEDA) (1.836 g, 15.784 mmol, 0.25 equiv.). Acetone (50 mL) was added, and as the solids dissolved the mixture became dark green. 4-ethynylbenzeneboronic acid pinacole ester (18 g, 78.8 mmol, 1.0 equiv.) was added to this mixture, which was then stirred for 16 hours. The solvent was removed by rotary evaporation to yield a green residue that was washed with H₂O (300 mL). The resultant solid was isolated via filtration through a Bilchener funnel. This solid was subsequently recrystallized from CH₃CN as a white solid, collected via filtration through a Büchener funnel, and dried under vacuum (5.25 g, 12 mmol, 30%). ¹H NMR analysis of this product was consistent with a previous report.⁵ ¹H-NMR (CDCl₃, 400 MHz, 298 K) δ 7.65 (d, J=9.0 Hz, 4H); 7.52 (d, J=9.0 Hz, 4H); 1.34 (s, 24H).

Synthesis of 4,4′-diphenylbutadiynebis(boronic acid). The synthesis of this compound was adapted from a previous report. 5 In a 20 mL scintillation vial, 4,4′ -diphenylbutadiyne pinacole borane (1.00 g, 2.20 mmol, 1.00 equiv.) and sodium periodate (1.0 g, 5.00 mmol, 2.27 equiv.) were dissolved in THF:H2O (4:1 v/v, 30 mL). This mixture was stirred at room temperature with nitrogen actively bubbling through it for 30 minutes, after which 1M HCl (5 mL) was added via syringe. The reaction vessel was subsequently sealed and allowed to stir for an additional 24 hours. At this point, the reaction mixture was poured into 100 mL of H₂O, filtered through a Buchener funnel, and washed with an additional 100 mL of H2O. This product was then flushed with 100 mL of diethyl ether. This powder was dried under vacuum for 10 minutes to afford a fine white powder (444 mg, 1.5 mmol, 69%). ¹H NMR analysis of this product was consistent with a previous report.5 ¹H-NMR (DMSO-d₆, 400 MHz, 298 K) δ 8.26 (s, 4H); 7.82 (d, J=7.5 Hz, 4H); 7.57 (d, J=7.5 Hz, 4H).

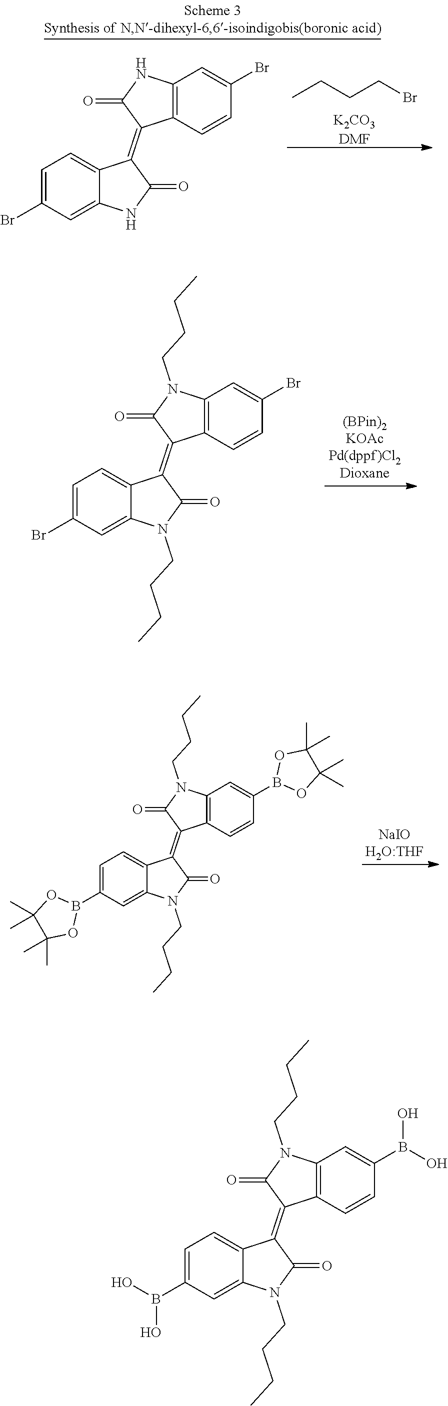

Synthesis of N,N′-dibutyl-6,6′-bisbromoisoindigo. To a flame-dried 300 mL RBF, dibromoisoinidio (750 mg, 1.785 mmol, 1.0 equiv.), K₂CO₃ (1.65 g, 11.90 mmol, 6.67 equiv.), and DMF (32 mL) were added. Then, butylbromide (0.56 mL, 5.24 mmol, 2.93 equiv.) was added via syringe and heated to 110° C. After 14 hours, the reaction mixture was cooled to room temperature and quenched with saturated NH₄Cl. The product was then extracted with EtOAc (2×100 mL). These fractions were then combined, washed with water (5×100 mL) and brine (2×100 mL). The organic fraction was then collected, dried with anhydrous MgSO₄, filtered, and concentrated in vacuo to give N,N′-dihexyl-6,6′-bisbromoisoindigo as a deep red product (590 mg, 1.1 mmol, 62%). ¹H NMR analysis of this product was consistent with a previous report.⁶ ¹H NMR (400 MHz, cdcl₃) δ 9.07 (d, J=8.6 Hz, 1H), 7.17 (dd, J=8.6, 1.9 Hz, 1H), 6.93 (d, J=1.9 Hz, 1H), 3.74 (t, J=7.4 Hz, 2H), 1.66 (d, J=7.4 Hz, 2H), 1.41 (d, J=7.8 Hz, 2H), 0.97 (t, J=7.4 Hz, 3H).

Synthesis of N,N′-dibutyl-6,6′-isoindigobis(pinacolborane). The following were added to a 50 mL Schlenk flask: N,N′-dihexyl-6,6′-bisbromoisoindigo (500 mg, 0.94 mmol, 1.0 equiv.), (BPin)₂ (596 mg, 2.35 mmol, 2.5 equiv), KOAc (332 mg, 3.38 mmol, 3.6 equiv.), Pd(dppf)Cl₂.CH₂Cl₂ (80 mg, 0.09 mmol, 0.10 equiv.), and 1,4-dioxane (8 mL). This flask was then closed with a septum and degassed under constant N₂ flow for 15 min. The reaction mixture was then heated at 80° C. for 40 hrs. Then, the reaction was cooled to room temperature and diluted with CH₂Cl₂. This mixture was then passed through a silica gel plug on a fritted funnel and washed with CH₂Cl₂. The filtrate was then concentrated in vacuo to yield a sticky red residue, which was mixed with MeOH (15 mL) and placed in a freezer. After 2 hrs, the precipitate was collected and dried to give N,N′-dihexyl-6,6′-isoindigobis(pinacolborane) as a deep red product (510 mg, 0.82 mmol, 87%). ¹H NMR analysis of this product was consistent with a previous report.⁶ ¹H NMR (499 MHz, cdcl₃) δ 9.15 (d, J=7.9 Hz, 1H), 7.49 (dd, J=7.9, 1.1 Hz, 1H), 7.15 (s, 1H), 3.81 (t, J=7.4 Hz, 2H), 1.73-1.68 (m, 2H), 1.46-1.41 (m, 2H), 1.37 (s, 12H), 0.97 (t, J=7.4 Hz, 3H).

Synthesis of N,N′-dibutyl-6,6′-isoindigobis(boronic acid). To a 20 mL scintillation vial N,N′-dihexyl-6,6′-isoindigobis(pinacolborane) (100 mg, 0.16 mmol, 1.0 equiv.), NaIO4 (85 mg, 0.4 mmol, 2.5 equiv.), a THF:H₂O 4:1 vol. (15 mL) were added. The vial was then placed under N₂. After 3 days, the reaction was diluted with H₂O (15 mL) and filtered while continuously adding water (50 mL), taking care to not let the product dry to completion on the filter paper. Finally, the product was washed with hexanes and dried under vacuum. This yielded N,N′-dihexyl-6,6′-isoindigobis(boronic acid) as a bright red solid (52 mg, 0.112 mmol, 70% yield). Reliable NMR analysis was not possible due to insolubility of the product.

### 2D COF Film Synthetic Procedures

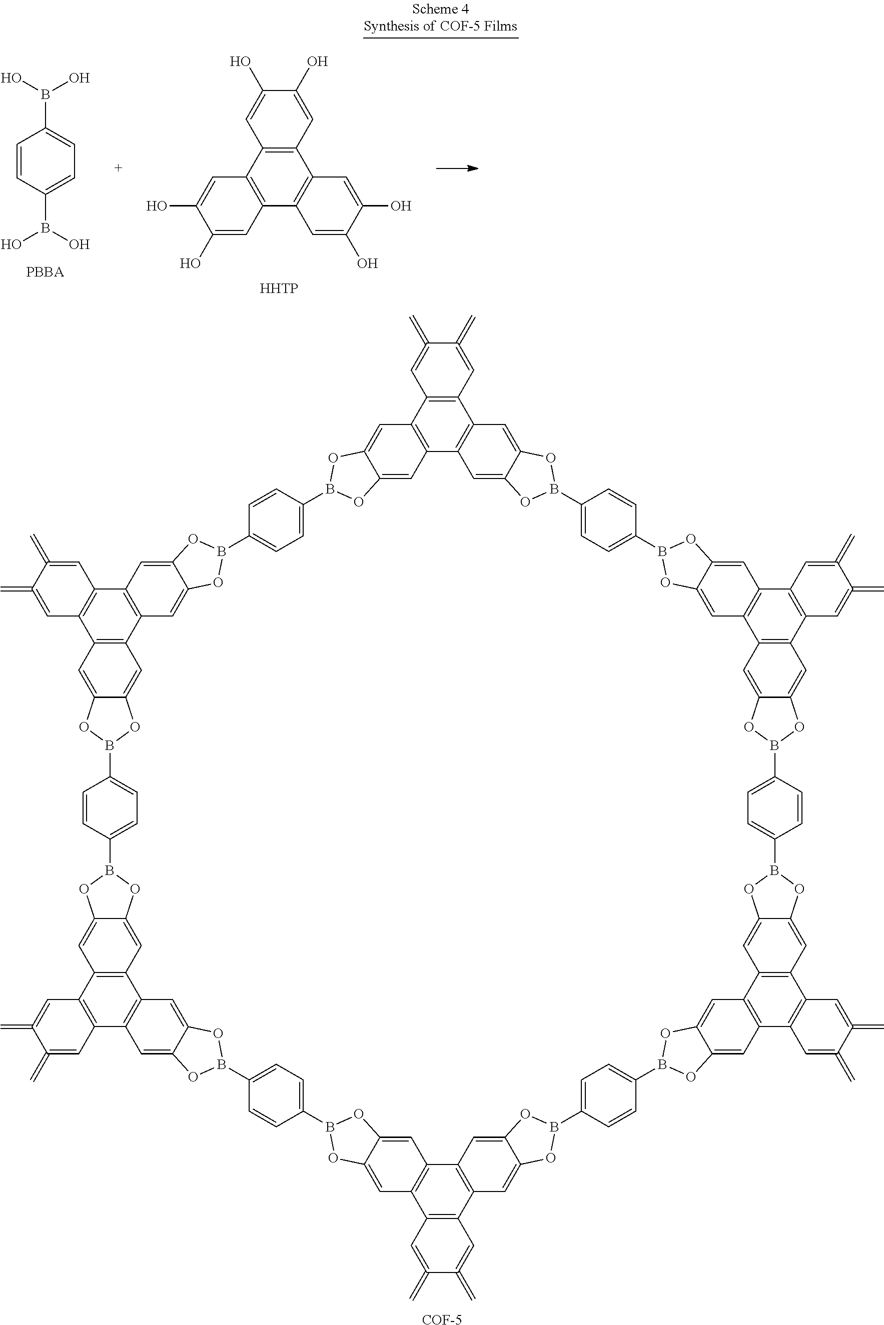

2D COF-5 Films. First, a graphene-coated Si/SiO₂ (1 cm×1 cm, UniversityWafer, Inc.) was placed into a scintillation vial. Then, solutions of HHTP (2 mM) and PBBA (3 mM) were prepared separately in a solvent blend of 80/16/4 vol CH₃CN:1,4-dioxane:1,3,5-trimethylbenzene. These solutions were then filtered to remove any insoluble particulates. These solutions were then added in a 1:1 vol ratio to the substate-containing scintillation vial, producing a 20 mL solution of 1 mM HHTP and 1.5 mM PBBA. This scintillation vial was then sealed and heated to 80° C. for 24 hrs. After 24 hrs, a milky suspension had formed in the scintillation vial. Approximately 90% of the solution was then decanted and diluted with fresh 80/16/4 vol CH₃CN:1,4-dioxane:1,3,5-trimethylbenzene. This procedure was repeated 3 times to sufficiently dilute any colloidal species present in solution. The wafer was then removed from solvent with forceps and allowed to dry in air.

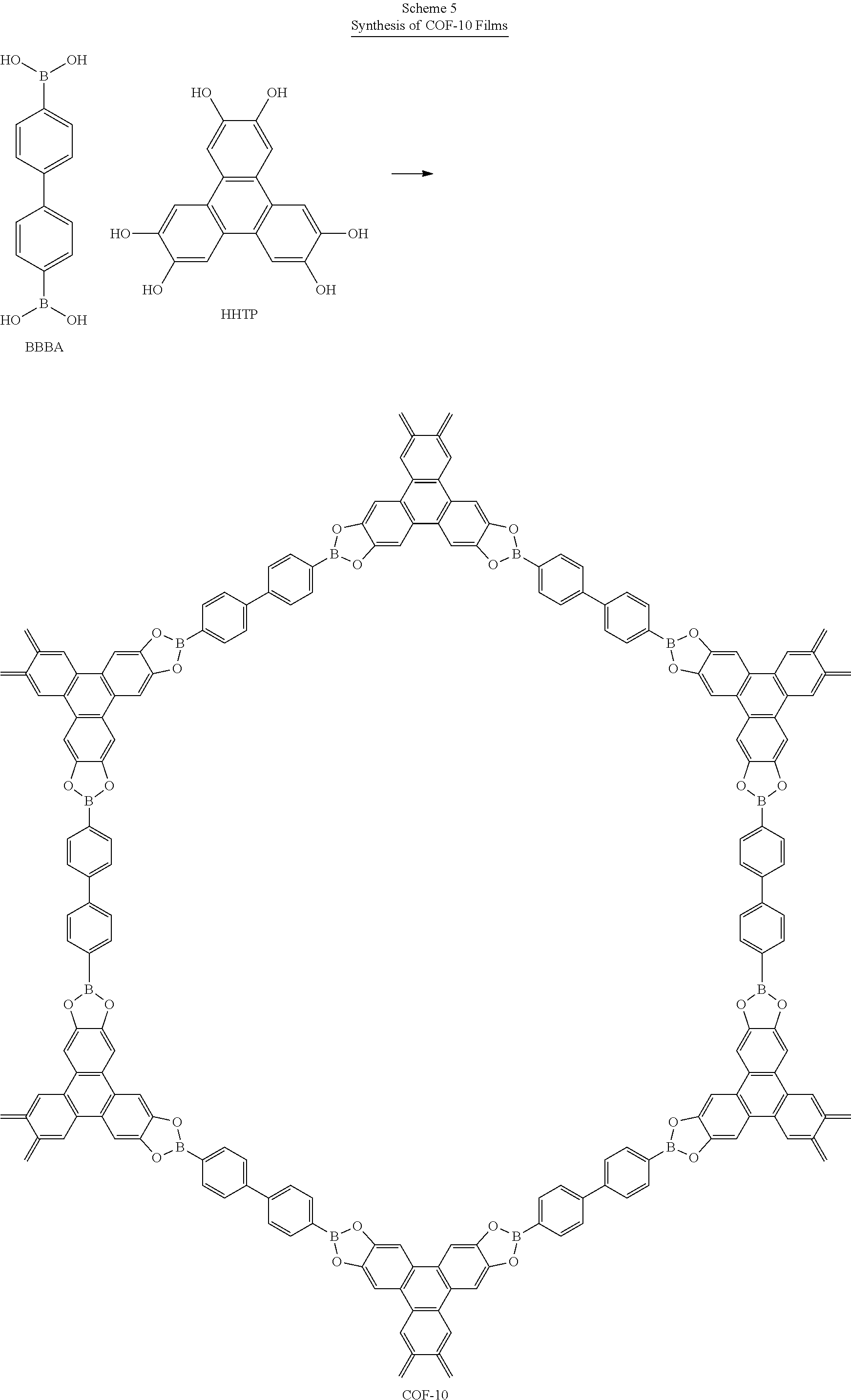

2D COF-10 Films. First, a graphene-coated Si/SiO₂ (1 cm×1 cm, University Wafer, Inc.) was placed into a scintillation vial. Then, solutions of HHTP (2 mM) and BBBA (3 mM) were prepared separately in a solvent blend of 80/16/4 vol CH₃CN:1,4-dioxane:1,3,5-trimethylbenzene. These solutions were then filtered to remove any insoluble particulates. These solutions were then added in a 1:1 vol ratio to the substate-containing scintillation vial, producing a 20 mL solution of 1 mM HHTP and 1.5 mM BBBA. This scintillation vial was then sealed and heated to 80° C. for 24 hrs. After 24 hrs, a milky suspension had formed in the scintillation vial. Approximately 90% of the solution was then decanted and diluted with fresh 80/16/4 vol CH₃CN:1,4-dioxane:1,3,5-trimethylbenzene. This procedure was repeated 3 times to sufficiently dilute any colloidal species present in solution. The wafer was then removed from solvent with forceps and allowed to dry in air.

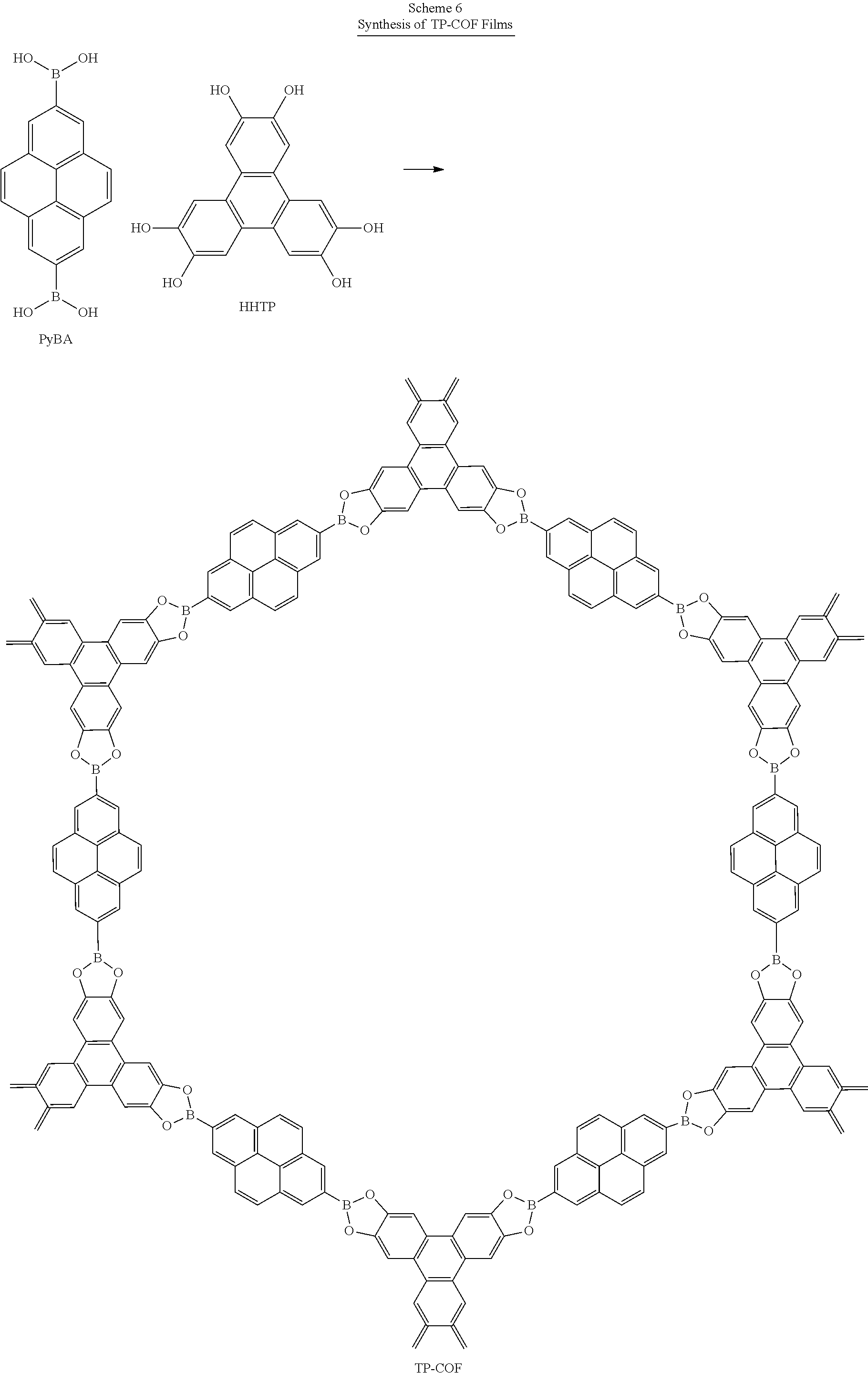

2D TP-COF Films. First, a graphene-coated Si/SiO2 (1 cm×1 cm, University Wafer, Inc.) was placed into a scintillation vial. Then, solutions of HHTP (2 mM) and PyBA (3 mM) were prepared separately in a solvent blend of 80/16/4 vol CH₃CN:1,4-dioxane:1,3,5-trimethylbenzene. These solutions were then filtered to remove any insoluble particulates. These solutions were then added in a 1:1 vol ratio to the substate-containing scintillation vial, producing a 20 mL solution of 1 mM HHTP and 1.5 mM PyBA. This scintillation vial was then sealed and heated to 80° C. for 24 hrs. After 24 hrs, a milky suspension had formed in the scintillation vial. Approximately 90% of the solution was then decanted and diluted with fresh 80/16/4 vol CH₃CN:1,4-dioxane:1,3,5-trimethylbenzene. This procedure was repeated 3 times to sufficiently dilute any colloidal species present in solution. The wafer was then removed from solvent with forceps and allowed to dry in air.

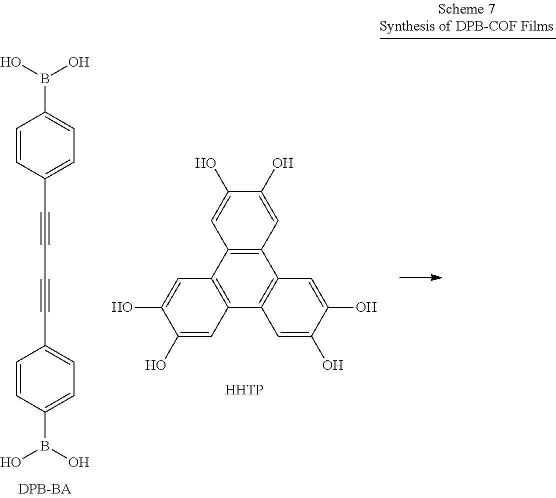 [SMILES: OB(O)c1ccc(C#CC#Cc2ccc(B(O)O)cc2)cc1 ; Oc1cc2c3cc(O)c(O)cc3c3cc(O)c(O)cc3c2cc1O ; "HHTP"]

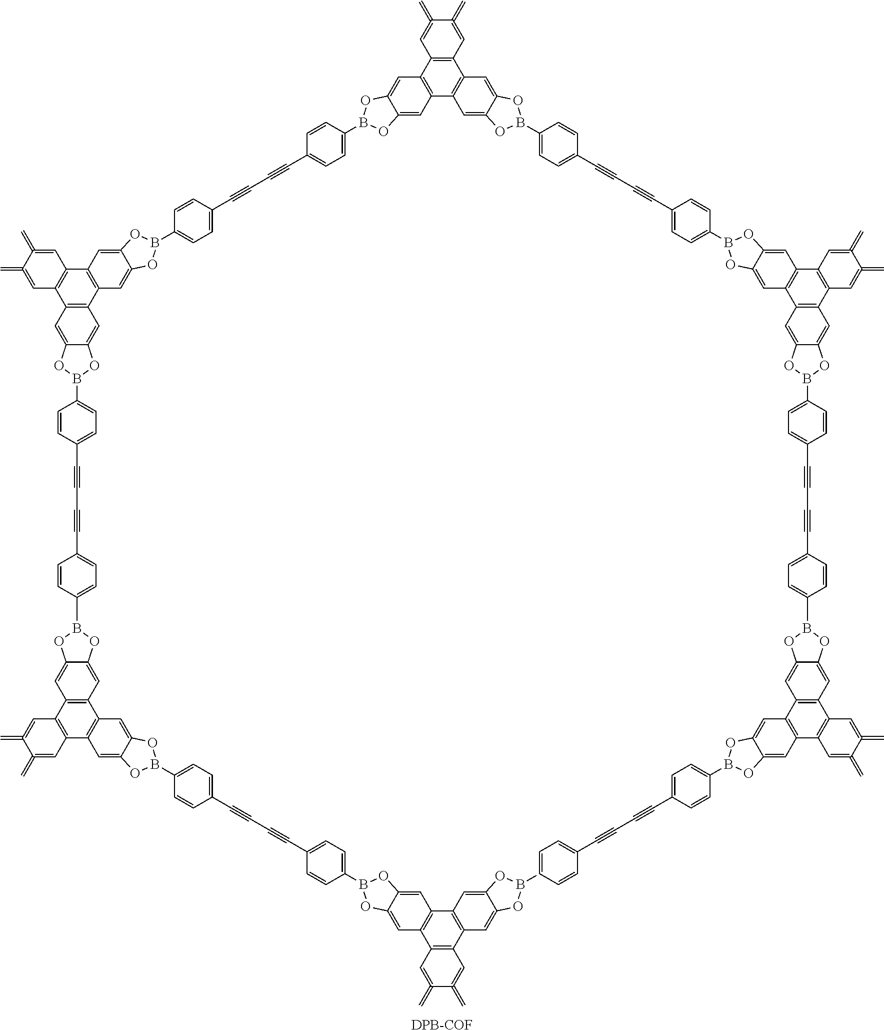

2D DPB-COF Films. First, a graphene-coated Si/SiO₂ (1 cm×1 cm, UniversityWafer, Inc.) was placed into a scintillation vial. Then, solutions of HHTP (2 mM) and DPB-BA (3 mM) were prepared separately in a solvent blend of 80/16/4 vol CH₃ CN:1,4-dioxane:1,3,5-trimethylbenzene. These solutions were then filtered to remove any insoluble particulates. These solutions were then added in a 1:1 vol ratio to the substate-containing scintillation vial, producing a 20 mL solution of 1 mM HHTP and 1.5 mM DPB-BA. This scintillation vial was then sealed and heated to 80° C. for 24 hrs. After 24 hrs, a milky suspension had formed in the scintillation vial. Approximately 90% of the solution was then decanted and diluted with fresh 80/16/4 vol CH₃CN:1,4-dioxane:1,3,5-trimethylbenzene. This procedure was repeated 3 times to sufficiently dilute any colloidal species present in solution. The wafer was then removed from solvent with forceps and allowed to dry in air.

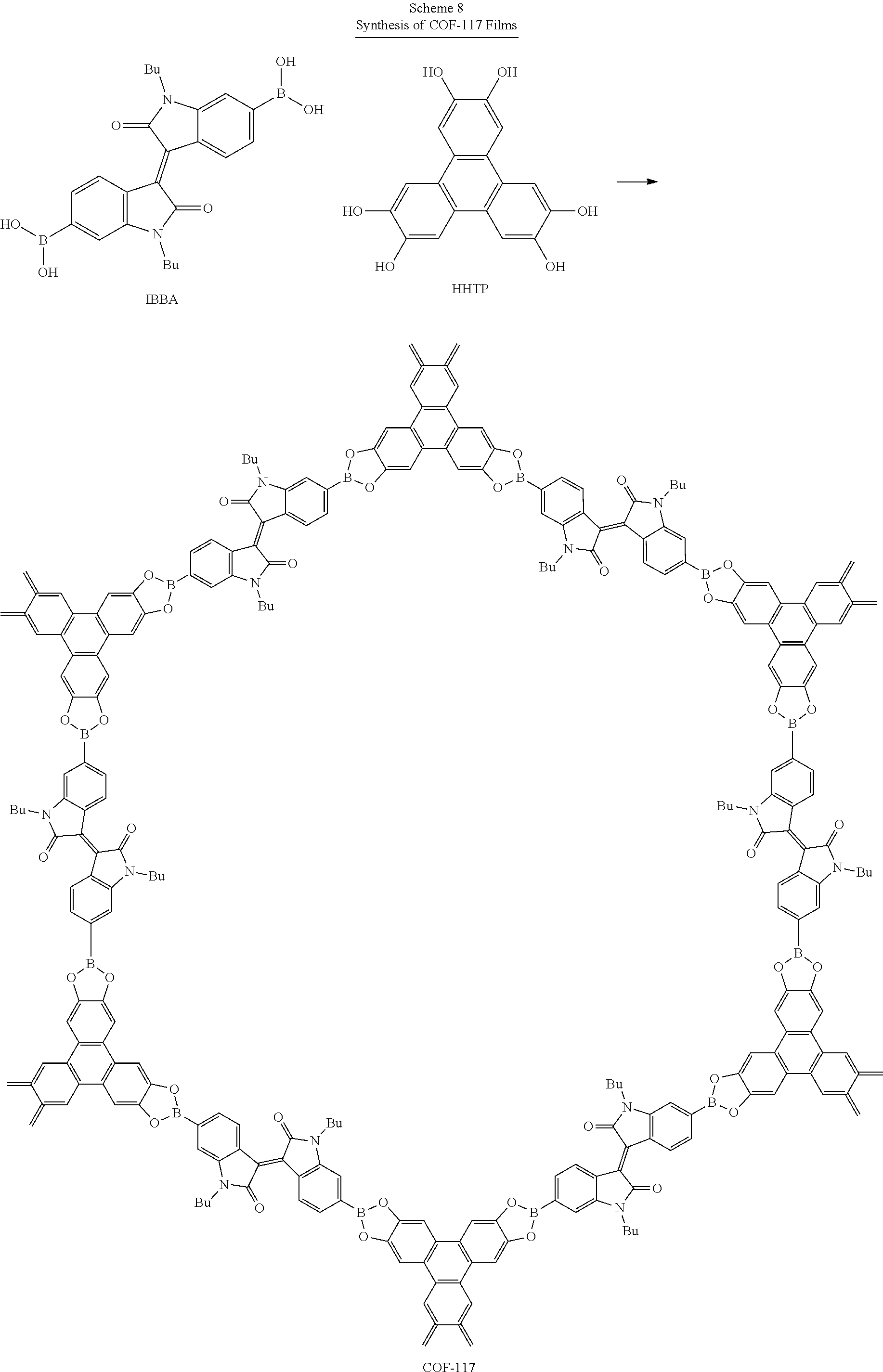

2D COF-117 Films. First, a graphene-coated Si/SiO2 (1 cm×1 cm, UniversityWafer, Inc.) was placed into a scintillation vial. Then, solutions of HHTP (2 mM) and IBBA (3 mM) were prepared separately in a solvent blend of 80/16/4 vol CH₃CN:1,4-dioxane:1,3,5-trimethylbenzene. These solutions were then filtered to remove any insoluble particulates. These solutions were then added in a 1:1 vol ratio to the substate-containing scintillation vial, producing a 20 mL solution of 1 mM HHTP and 1.5 mM IBBA. This scintillation vial was then sealed and heated to 80° C. for 24 hrs. After 24 hrs, a milky suspension had formed in the scintillation vial. Approximately 90% of the solution was then decanted and diluted with fresh 80/16/4 vol CH₃CN:1,4-dioxane:1,3,5-trimethylbenzene. This procedure was repeated 3 times to sufficiently dilute any colloidal species present in solution. The wafer was then removed from solvent with forceps and allowed to dry in air.

### 2D COF-5 Films Prepared at Different Concentrations

First, a graphene-coated Si/SiO2 (1 cm×1 cm, UniversityWafer, Inc.) was placed into a scintillation vial. Then, solutions of HHTP (10 mM) and PBBA (15 mM) were prepared separately in a solvent blend of 80/16/4 vol CH₃CN:1,4-dioxane:1,3,5-trimethylbenzene. These solutions were then filtered to remove any insoluble particulates.

These solutions were then mixed in a 1:1 vol ratio, which was then diluted with additional 80/16/4 vol CH₃CN:1,4-dioxane:1,3,5-trimethylbenzene to yield solutions with HHTP concentrations of 5 mM (PBBA=7.5 mM), 2 mM (PBBA=3 mM), 1 mM (PBBA=1.5 mM), and 0.5 mM (PBBA=0.75 mM). These solutions were then added to the scintillation vial that contained the graphene-supported substrate. This scintillation vial was then sealed and heated to 80° C. for 24 hrs. After 24 hrs, a milky suspension had formed in the scintillation vial. Approximately 90% of the solution was then decanted and diluted with fresh 80/16/4 vol CH₃CN:1,4-dioxane:1,3,5-trimethylbenzene. This procedure was repeated 3 times to sufficiently dilute any colloidal species present in solution. The wafer was then removed from solvent with forceps and allowed to dry in air.

### Multigrowth COF Films

First, a graphene-coated Si/SiO₂ (1 cm×1 cm, UniversityWafer, Inc.) was placed into a scintillation vial. Then, solutions of HHTP (2 mM) and corresponding boronic acid (3 mM) were prepared separately in a solvent blend of 80/16/4 vol CH₃CN:1,4-dioxane:1,3,5-trimethylbenzene. These solutions were then filtered to remove any insoluble particulates. These solutions were then mixed in a 1:1 vol ratio. This solution was then added to the scintillation vial that contained the graphene-supported substrate. This scintillation vial was then sealed and heated to 80° C. for 24 hrs. After 24 hrs, a milky suspension had formed in the scintillation vial. Approximately 90% of the solution was then decanted and diluted with fresh 80/16/4 vol CH₃CN:1,4-dioxane:1,3,5-trimethylbenzene. This procedure was repeated 3 times to sufficiently dilute any colloidal species present in solution.

Then, to instigate another round of growth, additional monomer species (prepared as described above) were added to the scintillation vial containing the wafer. This scintillation vial was then sealed and heated to 80° C. for 24 hrs. After 24 hrs, a milky suspension had formed in the scintillation vial. Approximately 90% of the solution was then decanted and diluted with fresh 80/16/4 vol CH₃CN:1,4-dioxane:1,3,5-trimethylbenzene. This procedure was repeated 3 times to sufficiently dilute any colloidal species present in solution. This procedure was repeated for as many times as described. Finally, the wafer was removed from solvent with forceps and allowed to dry in air.

### Time Domain Thermoreflectance (TDTR) Measurements

To prepare our samples for time-domain thermoreflectance (TDTR), we first deposit an 80 nm thick Al transducing layer via electron beam evaporation at 6·10⁻⁶ Torr. In our TDTR setup, sub-picosecond laser pulses emanate from a Ti:Saphhire oscillator at 80 MHz repetition rate. The pulses are separated into a pump path that heats up the sample and a time-delayed probe path that is reflected from the Al transducer. The reflected probe beam provides a measure of the change in the thermoreflectance due to the decay of the thermal energy deposited by the pump beam. A modulation of 8.8 MHz is applied by an electro-optic modulator on the pump beam and the ratio of the in-phase to out-of-phase signal of the reflected probe beam recorded at that frequency by a lock-in amplifier (−Vᵢₙ/Vₒᵤₜ) for up to 5.5 ns after the initial heating event. The pump and probe beams are focused on to the Al transducer at e⁻² radii values of 10 and 5 μm for our pump and probe spots, respectively.

To simultaneously measure the thermal conductivity and heat capacity of our COFs, we fit a three-layer thermal model to our experimental data. However, we first consider the appropriate range of pump-probe delay times, in which the thermal model is extremely sensitive to changes in the thermophysical quantities. This is quantified by the sensitivity of the ratio (Vᵢₙ/VNₒᵤₜ) to the various thermal properties defined by,

$$S α = \frac{\partial ln ( \frac{V i n}{V o u t} )}{\partial ln ( α )} \qquad ( 5 )$$

where α is the thermophysical parameter of interest.¹⁶ FIG. 19C shows the sensitivities of the ratio to thethermophysical parameters of the three-layer thermal model. The sensitivity to the thermal conductivity of COF-5, κ_{COF-5}, is relatively large compared to the other parameters for the entire time delay. The large and dynamic sensitivity of the heat capacity of our COF film (Cᵥ) also allows for the simultaneous measurement of these two physical properties with relatively good precision, therefore, we treat κ_{COF} and Cᵥ as adjustable parameters in our analytical model to fit the TDTR data for the entire pump-probe delay time.

Characteristic TDTR data and the best-fit of the thermal model for TP-COF at 8.8 MHz modulation frequency is shown in FIG. 19D-19E. FIG. 19D-19E shows the sensitivity contour plot describing the interrelationship between the measured heat capacity and thermal conductivity of TP-COF at 8.845 MHz modulation frequency. Note, the contour plot represents the mean square deviation of our thermal model to the TDTR data with the various combinations of heat capacity and thermal conductivity as input parameters.^{17,18} The standard deviation between our model and data is determined as,

$$σ = \frac{{\sum }_{j = 0}^{n} {( {R}_{m , j} - {R}_{d , j} )}^{2}}{n} \qquad ( 6 )$$

where Rₘ and Rd are the ratios from the model and data, respectively, and n is the total number of time delays considered.

### Thermal Boundary Conductance

From time-domain thermoreflectance measurements, we determine that the thermal resistivity of the Al/COF-5 boundary is minimal (FIG. 23). As observed from the analytical fits to our TDTR results with varying thermal boundary conductance (h_{K}) at the Al/COF interface, h_{K}<70 MW m⁻² K⁻¹ results in poor fits to the experimental data. In contrast, higher h_{K} values optimize the fits for the early pump-probe time delays (especially at t<1 ns). Moreover, increasing the value of h_{K}>100 MW m⁻² K⁻¹ at the Al/COF interface has negligible influence on the best-fit to our experimental data. These results suggest that h_{K} at Al/COF is considerably higher than the conductance of our COF films.

We plot sensitivity contour plots (FIG. 24) that represent the mean square deviation of the analytical model to our TDTR data with various combinations of thermal conductivity of COF (κ_{COF}) and h_{K,2} at COF/SLG/SiO₂ interface as input parameters in our three-layer model. A combination of low h_{K,2} (<30 MW m⁻² K⁻¹) and relatively high κ_{COF}(>1.3 W m⁻¹ K⁻¹) produce the best-fits suggesting that the resistance at the interface dominates heat transfer in the cross-plane direction. As such, we assign a lower bound of 30 MW m⁻² K⁻¹ to h_{K,2} from our measurements.

In the scenario where interfacial resistances dominate heat transfer, decreasing the film thickness will have a negligible effect on total thermal transport. However, if heat transfer is dominated by the intrinsic resistance of the film, a change in the thickness results in a noteable change in the total conductance across the sample. To differentiate between these different possibilities, we synthesized an additional COF-5 film with a different thickness of that measured previously. TDTR measurements (FIG. 25, open points) and two-layer thermal model (interfacial resistances considered as a single component) best fits (FIG. 25, solid lines) reveals a thermal conductivity thickness dependence. To show how the fits would change if interfacial resistance would be the dominant resistance in our model, we also plot predictions from a three-layer model where we prescribe a low conductance (high resistance) across the COF-5/SLG/SiO₂ (h_{K,2}˜10 MW m⁻² K⁻¹) for 40 nm and 80 nm COF-5 samples (dashed line and dotted-dashed lines, respectively). For the scenario where thermal transport is dominated by interfacial resistance, the model predicts similar behavior for the two thicknesses, which is inconsistent with our TDTR data.

### Frequency-Domain Thermoreflectance (FDTR)

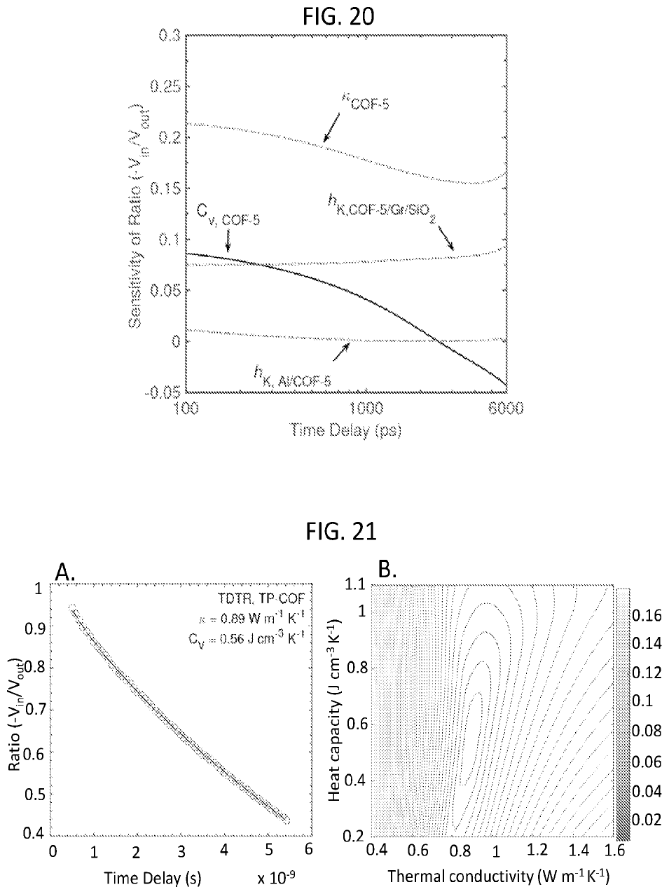

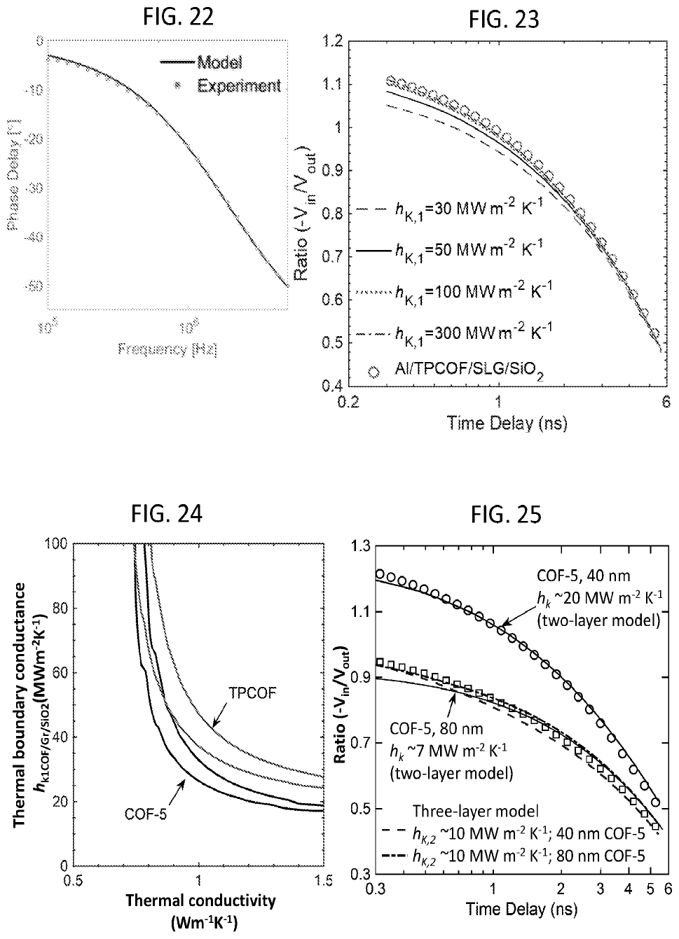

To cross-validate and gain confidence in our TDTR results, we perform Frequency domain thermoreflectance (FDTR) measurements on our COF-5 sample. Similar to TDTR, FDTR is also a laser-based metrology implemented to measure thermal properties of a sample.^{19,20} A thin (73.1 nm measured by KLA Tencor P-15 Profilometer) coating of Au is sputter deposited (PerkinElmer6J) on top of the sample. The Au-coated sample is periodically heated via a sinusoidally modulated (100 kHz-5 MHz) pump laser at 488 nm wavelength. The sample's temperature will fluctuate with the same frequency as the pump laser, but with a time delay. The phase delay is characteristic of the thermal properties of the sample. The temperature is measured using a concentric probe laser (532 nm), which is sensitive to the thermoreflectance of Au. The frequency-dependent time delay measured as a phase delay of the reflected probe laser with respect to the pump laser modulation frequency is measured with a photodiode connected to a lock-in amplifier. The phase delay, as shown in FIG. 20, is fit to an analytical solution to heat diffusion equation for a layered, semi-infinite solid to extract the thermal conductivity of the COF-5 sample. Our TDTR analysis also has sensitivity to the thermal boundary conductance across the COF-5/single layer graphene/SiO₂ interface. By using the heat capacities determined via MD and FDTR (see below), we fit for a thermal boundary conductance of ˜30 MW m⁻² K⁻¹, in reasonable agreement with previous measurements across similar (single layer graphene/SiO₂) interfaces.²¹

COF thermal conductivity is the targeted property, but its value depends on the heat capacity of the COF, which is also unknown. We evaluated the quality of the fit between the model and data based on the mean squared error (MSE). The MSE was calculated assuming a range of thermal conductivity and heat capacity combinations and averaged for four independent data sets. In FIG. S4 we plot the global minimum MSE and a contour at 1.2 times the global minimum MSE for two different spot radii (red for a radius of 3.2 μm and blue for a radius of 3.3 μm). The predicted values of thermal conductivity (κ_{COF}) and heat capacity (Cᵥ) are sensitive to the spot size. The contours indicate that a range of 0.5<κ<2 W m⁻¹ K⁻¹ and 0.33<C<0.63 J cm⁻³ K⁻¹ could be reasonably interpreted from the FDTR experiments. Though FDTR is less sensitive to κ than TDTR, the range of values for C and κ overlap (as shown in FIG. 21) and FDTR serves to strengthen the conclusion reached by TDTR.

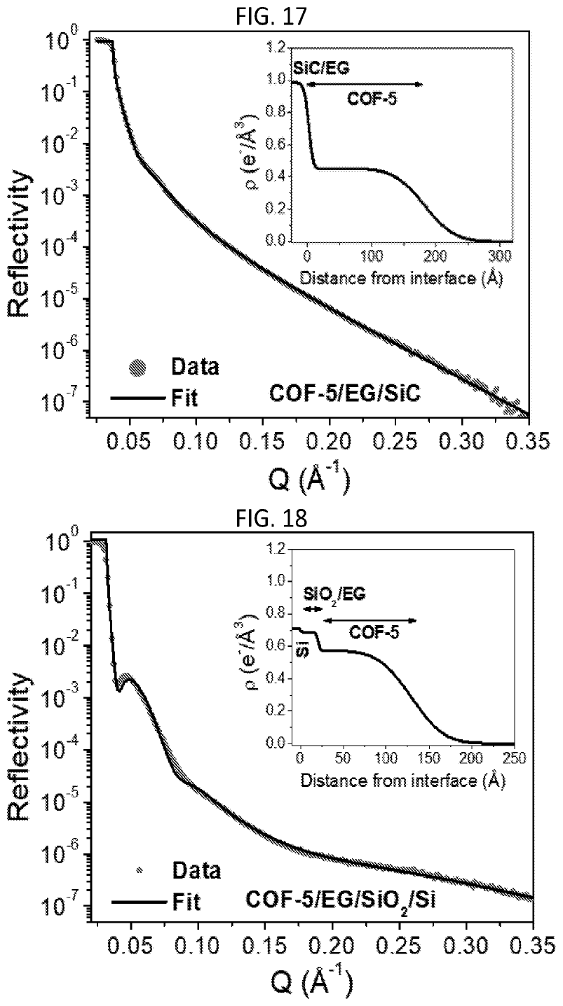

TABLE 4
XRR fitting parameters from FIG. 17.

| | Thickness (Å) | Roughness | e⁻ density (e⁻ Å⁻³) |
|---|---|---|---|
| COF-5 | 177.7 | 37.3 | 0.452 |
| EG | 4.0 | 4.6 | 0.678 |
| SiC | — | 5.6 | 0.983 |

TABLE 5
XRR fitting parameters from FIG. 18.

| | Thickness (Å) | Roughness (Å) | e⁻ density (e⁻ Å⁻³) |
|---|---|---|---|
| COF-5 | 108.8 | 30.4 | 0.573 |
| SiO₂/EG | 20.5 | 2.1 | 0.688 |
| Si | — | 1.0 | 0.709 |

TABLE 6
XRR fitting parameters from FIG. 3E.

| | Thickness (Å) | Roughness (Å) | e⁻ density (e⁻ Å⁻³) |
|---|---|---|---|
| Al₂O₃ | 75.1 | 38.7 | 1.192 |
| COF-5 | 168.9 | 38.5 | 0.452 |
| EG | 3.99 | 4.6 | 0.678 |
| SiC | — | 5.6 | 0.983 |

### REFERENCES

1 Jiang, Z. GIXSGUI: a MATLAB toolbox for grazing-incidence X-ray scattering data visualization and reduction, and indexing of buried three-dimensional periodic nanostructured films. J. Appl. Crystallogr. 48, 917-926 (2015).

2 Ilaysky, J. Nika: software for two-dimensional data reduction. J. Appl. Crystallogr. 45, 324-328 (2012).

3 Nelson, A. Co-refinement of multiple-contrast neutron/X-ray reflectivity data using MOTOFIT. J Appl. Crystallogr. 39, 273-276 (2006).

4 Wan, S., Guo, J., Kim, J., Thee, H. & Jiang, D. A belt-shaped, blue luminescent, and semiconducting covalent organic framework. Angew. Chem. Int. Ed. 47, 8826-8830 (2008).

5 Spitler, E. L. et al. A 2D covalent organic framework with 4.7-nm pores and insight into its interlayer stacking. J. Am. Chem. Soc. 133, 19416-19421 (2011).

6 Dharmapurikar, S. S., Arulkashmir, A., Das, C., Muddellu, P. & Krishnamoorthy, K. Enhanced hole carrier transport due to increased intermolecular contacts in small molecule based field effect transistors. ACS Appl. Mater. Inter. 5, 7086-7093 (2013).

7 Colson, J. W. et al. Oriented 2D covalent organic framework thin films on single-layer graphene. Science 332, 228-231 (2011).

8 Dovesi, R. et al. Quantum-mechanical condensed matter simulations with CRYSTAL. WIREs Computational Molecular Science 8, e1360, doi:10.1002/wcms.1360 (2018).

9 R. Dovesi, V. R. S., C. Roetti, R. Orlando, C. M. Zicovich-Wilson, F. Pascale, B. Civalleri, K. Doll, N. M. Harrison, I. J. Bush, P. D'Arco, M. Llunell, M. Causà, Y. Noël, L. Maschio, A. Erba, M. Rerat, S. Casassa. CRYSTAL17 User's Manual (University of Torino, Torino, 2017).

10 Adamo, C. & Barone, V. Toward reliable density functional methods without adjustable parameters: The PBE0 model. The Journal of Chemical Physics 110, 6158-6170, doi:10.1063/1.478522 (1999).

11 Peintinger, M. F., Oliveira, D. V. & Bredow, T. Consistent Gaussian basis sets of triple-zeta valence with polarization quality for solid-state calculations. Journal of Computational Chemistry 34, 451-459, doi :10.1002/j cc.23153 (2013).

12 Grimme, S., Ehrlich, S. & Goerigk, L. Effect of the damping function in dispersion corrected density functional theory. Journal of Computational Chemistry 32, 1456-1465, doi:10.1002/jcc.21759 (2011).

13 Gajdos̆, M., Hummer, K., Kresse, G., Furthmüller, J. & Bechstedt, F. Linear optical properties in the projector-augmented wave methodology. Physical Review B 73, 045112, doi :10.1103/PhysRevB .73.045112 (2006).

14 Perdew, J. P., Burke, K. & Ernzerhof, M. Generalized Gradient Approximation Made Simple. Physical Review Letters 77, 3865-3868, doi:10.1103/PhysRevLett.77.3865 (1996).

15 Gonze, X. Adiabatic density-functional perturbation theory. Physical Review A 52, 1096-1114, doi:10.1103/PhysRevA.52.1096 (1995).

16 Costescu, R. M., Wall, M. A. & Cahill, D. G. Thermal conductance of epitaxial interfaces. Phys. Rev. B 67, 054302 (2003).

17 Giri, A., Niemeld, J.-P., Szwejkowski, C. J., Karppinen, M. & Hopkins, P. E. Reduction in thermal conductivity and tunable heat capacity of inorganic/organic hybrid superlattices. Phys. Rev. B. 93, 024201 (2016).

18 Wang, X., Liman, C. D., Treat, N. D., Chabinyc, M. L. & Cahill, D. G. J. P. R. B. Ultralow thermal conductivity of fullerene derivatives. Phys. Rev. B 88, 075310 (2013).

19 Schmidt, A. J., Cheaito, R. & Chiesa, M. A frequency-domain thermoreflectance method for the characterization of thermal properties. Rev. Sci. Instrum. 80, 094901 (2009).

20 Malen, J. A. et al. Optical measurement of thermal conductivity using fiber aligned frequency domain thermoreflectance. J. Heat Trans. 133 (2011).

21 Koh, Y. K., Bae, M.-H., Cahill, D. G. & Pop, E. Heat conduction across monolayer and few-layer graphenes. Nano Lett. 10, 4363-4368 (2010).

22 Plimpton, S. J. Comp. Phys. 117, 1-19 (1995).

23 Stuart, S. J., Tutein, A. B. & Harrison, J. A. A reactive potential for hydrocarbons with intermolecular interactions. J. Chem. Phys. 112, 6472-6486 (2000).

24 Hoover, W. G. & Posch, H. A. Direct measurement of Lyapunov exponents. Phys. Let. A 113, 82-84 (1985).

25 Giri, A. & Hopkins, P. E. Resonant phonon modes in fullerene functionalized graphene lead to large tunability of thermal conductivity without impacting the mechanical properties. J. Appl. Phys. 125, 205102 (2019).

26 Salaway, R. N. & Zhigilei, L. V. Molecular dynamics simulations of thermal conductivity of carbon nanotubes: Resolving the effects of computational parameters. Int. J. Heat Mass Trans! 70, 954-964 (2014).

27 Lukes, J. R. & Zhong, H. Thermal conductivity of individual single-wall carbon nanotubes. J. Heat Trans. (2007).

28 Allen, M. P. & Tildesley, D. J. Computer simulation of liquids. (Oxford university press, 2017).

29 Schelling, P. K., Phillpot, S. R. & Keblinski, P. Comparison of atomic-level simulation methods for computing thermal conductivity. Phys. Rev. B 65, 144306 (2002).

30 McGaughey, A. & Kaviany, M. Thermal conductivity decomposition and analysis using molecular dynamics simulations. Part I. Lennard-Jones argon. Int. J. Heat Mass Transf. 47, 1783-1798 (2004).

31 McGaughey, A., Kaviany, M. J. I. J. o. H. & Transfer, M. Thermal conductivity decomposition and analysis using molecular dynamics simulations: Part II. Complex silica structures. Int. J. Heat Mass Transf. 47, 1799-1816 (2004).

32 Henry, A. S. & Chen, G. Spectral phonon transport properties of silicon based on molecular dynamics simulations and lattice dynamics. J. Comput. Theor. Nanos. 5, 141-152 (2008).

33 Wang, Z., Safarkhani, S., Lin, G. & Ruan, X. Uncertainty quantification of thermal conductivities from equilibrium molecular dynamics simulations. Int. J. Heat Mass Transf. 112, 267-278 (2017).

34 Lv, W. & Henry, A. Direct calculation of modal contributions to thermal conductivity via Green-Kubo modal analysis. New. J. Phys. 18, 013028 (2016).

35 Chalopin, Y., Esfarjani, K., Henry, A., Volz, S. & Chen, G. Thermal interface conductance in Si/Ge superlattices by equilibrium molecular dynamics. Phys. Rev. B 85, 195302 (2012).

36 Che, J. Ç. a. T., Deng W and Goddard. Thermal conductivity of diamond and related materials from molecular dynamics simulations. J. Chem. Phys. 113, 6888 (2000).

37 Chen, J., Zhang, G. & Li, B. How to improve the accuracy of equilibrium molecular dynamics for computation of thermal conductivity? Phys. Let. A 374, 2392-2396 (2010).

38 Volz, S. G. & Chen, G. Molecular-dynamics simulation of thermal conductivity of silicon crystals. Phys. Rev. B 61, 2651 (2000).

39 Dong, H., Fan, Z., Shi, L., Harju, A. & Ala-Nissila, T. Equivalence of the equilibrium and the nonequilibrium molecular dynamics methods for thermal conductivity calculations: From bulk to nanowire silicon. Phys. Rev. B 97, 094305 (2018).

40 Sun, L. & Murthy, J. Y. Domain size effects in molecular dynamics simulation of phonon transport in silicon. Appl. Phys. Let. 89, 171919 (2006).

41 Fan, Z. et al. Force and heat current formulas for many-body potentials in molecular dynamics simulations with applications to thermal conductivity calculations. Phys. rev. B 92, 094301 (2015).

42 Boone, P., Babaei, H., Wilmer, C. E. J. J. o. c. t. & computation. Heat flux for many-body interactions: Corrections to LAMMP S. J. Chem. Theory Comp. 15, 5579-5587 (2019).

43 Sellan, D. P., Landry, E. S., Turney, J., McGaughey, A. J. & Amon, C. H. Size effects in molecular dynamics thermal conductivity predictions. Phys. Rev. B 81, 214305 (2010).

44 Braun, J. L., Szwejkowski, C. J., Giri, A. & Hopkins, P. E. On the steady-state temperature rise during laser heating of multilayer thin films in optical pump—probe techniques. J. Heat Transfer 140 (2018).

We claim:

1. A two-dimensional covalent organic framework, wherein the two-dimensional covalent organic framework comprises a regularly porous, covalently linked, layered structure, wherein the dielectric constant k is less than 2.4.

2. The covalent organic framework of claim 1, wherein the dielectric constant k is less than 1.9.

3. The covalent organic framework of any one of claims 1-2, wherein thermal conductivity K is greater than 0.8 W m⁻¹K⁻¹ in a cross-plane direction.

4. The covalent organic framework of any one of claims 1-3, wherein the thermal conductivity anisotropy ratio is greater than 3 between an in-plane thermal conductivity and a cross-plane thermal conductivity.

5. The covalent organic framework of any one of claims 1-4, wherein the density p is less than 1 g cm⁻³.

6. The covalent organic framework of any one of claims 1-5, wherein the covalent organic framework has a cross-plane thickness of less than 75 nm.

7. The covalent organic framework of any one of claims 1-6, wherein the two-dimensional covalent organic framework has a root-mean-square roughness less than 5 nm.

8. The covalent organic framework of any one of claims 1-7, wherein the two-dimensional covalent organic framework is a boronate ester-linked COF.

9. The covalent organic framework of claim 8, wherein the boronate ester-linked COF is prepared from poly-ol or catechol and a difunctional aryl boronic acid.

10. The covalent organic framework of claim 9, wherein the difunctional aryl boronic acid is PBBA, PyBA, BBBA, DPB-BA, or IBBA.

11. A heterostructure, the heterostructure comprising the two-dimensional covalent organic framework according to claim 1 and a templating substrate.

12. The heterostructure of claim 11, wherein the templating substrate comprises monolayer graphene or monolayer MoS₂.

13. The heterostructure of claim 12, wherein the templating substrate comprises a support.

14. The heterostructure of claim 13, wherein the support comprises Si.

15. The heterostructure of any one of claims 11-14, wherein the two-dimensional covalent organic framework is the two-dimensional covalent organic framework according to any one of claims 2-10.

16. A dielectric bilayer, the dielectric bilayer comprising the two-dimensional covalent organic framework according to claim 1 and a blocking layer configured to minimize leakage current.

17. The dielectric bilayer of claim 16, wherein the blocking layer comprises an inorganic dielectric layer.

18. The dielectric bilayer of claim 17, wherein the blocking layer comprises Al₂O₃, HfO₂, ZrO₂, ZnO, TiO₂, SiO₂, or Ta₂O₅.

19. The dielectric bilayer of any one of claims 16-18, wherein the blocking layer has a cross-plane thickness of less than 10 nm.

20. The dielectric bilayer of any one of claims 16-19, wherein the two-dimensional covalent organic framework is the two-dimensional covalent organic framework according to any one of claims 2-10.

21. A capacitor, the capacitor comprising the two-dimensional covalent organic framework according to claim 1 positioned between two conductive plates.

22. The capacitor of claim 21, wherein one of the two plates comprises a templating substrate in contact with the two-dimensional covalent organic framework.

23. The capacitor of claim 22, wherein the templating substrate comprises monolayer graphene or monolayer MoS₂.

24. The capacitor of any one of claims 22-23, wherein the templating substrate further comprises a support.

25. The capacitor of claim 24, wherein the support comprises Si.

26. The capacitor of any one of claims 21-25, wherein the capacitor comprises the two-dimensional covalent organic framework according any one of claims 2-9 or the dielectric bilayer according to any one of claims 16-19.

27. A method for preparing the two-dimensional covalent organic framework thin film, the method comprising:
contacting a solution with a templating substrate in a reaction vessel under conditions sufficient for preparing a covalent organic framework, whereby a heterotructure comprising a first layer of two-dimensional covalent organic framework deposited on the templating substrate and a liquid phase is formed within the reaction vessel; and
(b) removing an insoluble covalent organic framework dispersed within the liquid phase, wherein the solution comprises a plurality of building units, a plurality of linking units, and a solvent.

28. The method of claim 27, wherein the insoluble covalent organic framework dispersed within the liquid phase is solution-stable.

29. The method of any one of claims 27-28, wherein the solvent comprises a Lewis basic solvent.

30. The method of claim 29, wherein the Lewis basic solvent comprises a nitrile.

31. The method of claim 29, wherein the solvent comprises CH₃CN, a dioxane, and a substituted benzene.

32. The method of any one of claims 27-31, further comprising:
contacting the heterostructure with the solution in the reaction vessel having the insoluble covalent organic framework removed therefrom under conditions sufficient for preparing the covalent organic framework, whereby an additional layer of two-dimensional covalent organic framework is deposited on the heterostructure.

33. The method of claim 32, wherein contacting the heterostructure with the solution is repeated one or more times.

34. The method of any one of claims 27-33, wherein the removing step comprises removing a portion of the liquid phase from the reaction vessel and diluting, with additional solvent, the liquid phase remaining within the reaction vessel.

35. The method of claim 34, wherein at least 80% of the liquid phase is removed.

36. The method of any one of claims 27-35, wherein the templating substrate comprises monolayer graphene or monolayer MoS₂.

37. The method of any one of claims 27-36, method prepares the covalent organic framework according to any one of claims 1-10 or the heterostructure according to any one of claims 11-15.
